(19) United States
(12) Patent Application Publication
(10) Pub. No.: US 2024/0006432 A1
(43) Pub. Date: Jan. 4, 2024

(54) IMAGING DEVICE

(71) Applicant: SONY SEMICONDUCTOR SOLUTIONS CORPORATION, KANAGAWA (JP)

(72) Inventor: HIROMASA SAITO, KANAGAWA (JP)

(21) Appl. No.: 18/252,662

(22) PCT Filed: Sep. 6, 2021
(86) PCT No.: PCT/JP2021/032661

§ 371 Date: May 11, 2023

(30) Foreign Application Priority Data
Nov. 20, 2020 (JP) 2020-193592

(51) Int. Cl. H01L 27/146

(52) U.S. Cl. CPC H01L 27/14614; H01L 27/14607; H04N 25/77

(57) ABSTRACT

An imaging device according to an embodiment of the present disclosure includes: a pixel; a first transistor; first separation sections; and a second separation section. In the pixel, a plurality of photoelectric conversion regions is formed side by side in a plane of a semiconductor substrate. The first transistor is provided above each of the plurality of photoelectric conversion regions. The first transistor extracts electric charge generated in each of the plurality of photoelectric conversion regions. The first separation sections are continuously provided around the plurality of photoelectric conversion regions. The second separation section is provided adjacent to the first separation sections between the plurality of adjacent photoelectric conversion regions. The second separation section has a predetermined electric potential indirectly applied thereto by individually applying electric potentials to a layer below the first transistor and the first separation sections.

### TECHNICAL FIELD

The present disclosure relates to an imaging device including a plurality of photoelectric conversion regions in a pixel.

### BACKGROUND ART

For example, PTL 1 discloses an imaging device that is provided with a separation region between a plurality of photoelectric conversion sections provided in one pixel. The imaging device is provided with a gate electrode of a potential control switch on this separation region. This controls a height of a potential of the separation region between the plurality of photoelectric conversion sections.

### CITATION LIST

### Patent Literature

PTL 1: Japanese Unexamined Patent Application Publication No. 2013-41890

### SUMMARY OF THE INVENTION

Incidentally, an imaging device is requested to achieve both distance measurement performance and imaging performance.

It is desirable to provide an imaging device that makes it possible to achieve both distance measurement performance and imaging performance.

An imaging device according to an embodiment of the present disclosure includes: a pixel; a first transistor; first separation sections; and a second separation section. In the pixel, a plurality of photoelectric conversion regions is formed side by side in a plane of a semiconductor substrate. The first transistor is provided above each of the plurality of photoelectric conversion regions. The first transistor extracts electric charge generated in each of the plurality of photoelectric conversion regions. The first separation sections are continuously provided around the plurality of photoelectric conversion regions. The second separation section is provided adjacent to the first separation sections between the plurality of adjacent photoelectric conversion regions. The second separation section has a predetermined electric potential indirectly applied thereto by individually applying electric potentials to a layer below the first transistor and the first separation sections.

The imaging device according to the embodiment of the present disclosure is provided with the first separation sections and the second separation section in the one pixel including the plurality of photoelectric conversion regions disposed side by side in the plane of the semiconductor substrate. The electric potentials are individually applied to the layer below the first transistor provided above each of the plurality of photoelectric conversion regions and the first separation sections to indirectly adjust the electric potential of the second separation section. The first separation sections surround the plurality of respective photoelectric conversion regions. The second separation section is adjacent to the first separation sections between the plurality of adjacent photoelectric conversion regions. Accordingly, the potentials of the first separation sections and the second separation section are each adjusted as appropriate at a desired value after a wafer is fabricated.

### BRIEF DESCRIPTION OF DRAWING

FIG. 1 is a block diagram illustrating an example of a functional configuration of an imaging device according to an embodiment of the present disclosure.

FIG. 2 is a plane schematic diagram illustrating a schematic configuration of the imaging device illustrated in FIG. 1.

FIG. 3 is a schematic diagram illustrating a cross-sectional configuration taken along an I-I′ line illustrated in FIG. 2.

FIG. 4 is an equivalent circuit diagram of a pixel sharing unit illustrated in FIG. 1.

FIG. 5 is a diagram illustrating an example of a coupling mode between the plurality of pixel sharing units and a plurality of vertical signal lines.

FIG. 6 is a cross-sectional schematic diagram illustrating an example of a specific configuration of the imaging device illustrated in FIG. 3.

FIG. 7 is a schematic diagram illustrating an example of a planar configuration of a first substrate illustrated in FIG. 6.

FIG. 8 is a schematic diagram illustrating a cross-sectional configuration of the imaging device taken along an II-IT line illustrated in FIG. 7.

FIG. 9 is an equivalent circuit diagram of a pixel sharing unit illustrated in FIG. 6.

FIG. 10A is a schematic diagram illustrating a cross-sectional configuration taken along an A-A′ line illustrated in FIG. 7.

FIG. 10B is a schematic diagram illustrating a cross-sectional configuration taken along a B-B′ line illustrated in FIG. 7.

FIG. 10C is a schematic diagram illustrating a cross-sectional configuration taken along a C-C′ line illustrated in FIG. 7.

FIG. 10D is a schematic diagram illustrating a cross-sectional configuration taken along a D-D′ line illustrated in FIG. 7.

FIG. 10E is a schematic diagram illustrating a cross-sectional configuration taken along an E-E′ line illustrated in FIG. 7.

FIG. 11 is a schematic diagram for describing a path of an input signal to the imaging device illustrated in FIG. 3.

FIG. 12 is a schematic diagram for describing a signal path of a pixel signal of the imaging device illustrated in FIG. 3.

FIG. 13A is a diagram illustrating a potential of each of sections of a pixel illustrated in FIG. 7 in an electric charge accumulation period during autofocusing.

FIG. 13B is a diagram illustrating a potential of each of the sections of the pixel illustrated in FIG. 7 in a non-selection period during autofocusing.

FIG. 13C is a diagram illustrating a potential of each of the sections of the pixel illustrated in FIG. 7 in a readout period during autofocusing.

FIG. 14A is a diagram illustrating a potential of each of the sections of the pixel illustrated in FIG. 7 in an electric charge accumulation period during imaging.

FIG. 14B is a diagram illustrating a potential of each of the sections of the pixel illustrated in FIG. 7 in a non-selection period during imaging.

FIG. 14C is a diagram illustrating a potential of each of the sections of the pixel illustrated in FIG. 7 in a readout period during imaging.

FIG. 15A is a diagram illustrating a potential of each of the sections of the pixel illustrated in FIG. 7 in an electric charge accumulation period at low illuminance.

FIG. 15B is a diagram illustrating a potential of each of the sections of the pixel illustrated in FIG. 7 in a non-selection period at low illuminance.

FIG. 15C is a diagram illustrating a potential of each of the sections of the pixel illustrated in FIG. 7 in a readout period at low illuminance.

FIG. 16A is a diagram illustrating a potential of each of the sections of the pixel illustrated in FIG. 7 in an electric charge accumulation period at high illuminance.

FIG. 16B is a diagram illustrating a potential of each of the sections of the pixel illustrated in FIG. 7 in a non-selection period at high illuminance.

FIG. 16C is a diagram illustrating a potential of each of the sections of the pixel illustrated in FIG. 7 in a readout period at high illuminance.

FIG. 17A is a diagram illustrating a potential of each of the sections of the pixel illustrated in FIG. 7 in an electric charge accumulation period in a case of a high gain.

FIG. 17B is a diagram illustrating a potential of each of the sections of the pixel illustrated in FIG. 7 in a non-selection period in the case of the high gain.

FIG. 17C is a diagram illustrating a potential of each of the sections of the pixel illustrated in FIG. 7 in a readout period in the case of the high gain.

FIG. 18A is a diagram illustrating a potential of each of the sections of the pixel illustrated in FIG. 7 in an electric charge accumulation period in a case of a low gain.

FIG. 18B is a diagram illustrating a potential of each of the sections of the pixel illustrated in FIG. 7 in a non-selection period in the case of the low gain.

FIG. 18C is a diagram illustrating a potential of each of the sections of the pixel illustrated in FIG. 7 in a readout period in the case of the low gain.

FIG. 19 is a schematic diagram illustrating an example of a planar configuration of an imaging device according to a modification example 1 of the present disclosure.

FIG. 20 is a schematic diagram illustrating an example of a planar configuration of a first substrate of an imaging device according to a modification example 2 of the present disclosure.

FIG. 21A is a schematic diagram illustrating a cross-sectional configuration taken along an A-A′ line illustrated in FIG. 20.

FIG. 21B is a schematic diagram illustrating a cross-sectional configuration taken along a B-B′ line illustrated in FIG. 20.

FIG. 21C is a schematic diagram illustrating a cross-sectional configuration taken along a C-C′ line illustrated in FIG. 20.

FIG. 21D is a schematic diagram illustrating a cross-sectional configuration taken along a D-D′ line illustrated in FIG. 20.

FIG. 21E is a schematic diagram illustrating a cross-sectional configuration taken along an E-E′ line illustrated in FIG. 20.

FIG. 22A is a diagram illustrating a potential of each of the sections of the pixel illustrated in FIG. 20 in an electric charge accumulation period.

FIG. 22B is a diagram illustrating a potential of each of the sections of the pixel illustrated in FIG. 20 in a non-selection period.

FIG. 22C is a diagram illustrating a potential of each of the sections of the pixel illustrated in FIG. 20 in a readout period.

FIG. 23 is a schematic diagram illustrating an example of a cross-sectional configuration of an imaging device according to the present disclosure.

FIG. 24 is a schematic diagram illustrating another example of the cross-sectional configuration according to the present disclosure.

FIG. 25 is a schematic diagram illustrating another example of the cross-sectional configuration according to the present disclosure.

FIG. 26 is a diagram illustrating an example of a schematic configuration of an imaging system including the imaging device according to any of the embodiment described above and the modification examples thereof.

FIG. 27 is a diagram illustrating an example of an imaging procedure of the imaging system illustrated in FIG. 26.

FIG. 28 is a block diagram depicting an example of schematic configuration of a vehicle control system.

FIG. 29 is a diagram of assistance in explaining an example of installation positions of an outside-vehicle information detecting section and an imaging section.

FIG. 30 is a view depicting an example of a schematic configuration of an endoscopic surgery system.

FIG. 31 is a block diagram depicting an example of a functional configuration of a camera head and a camera control unit (CCU).

### MODES FOR CARRYING OUT THE INVENTION

The following describes an embodiment of the present disclosure in detail with reference to the drawings. The following description is a specific example of the present disclosure, but the present disclosure is not limited to the following modes. In addition, the present disclosure is not also limited to the disposition, dimensions, dimension ratios, and the like of the respective components illustrated in the respective diagrams. It is to be noted that description is given in the following order.
1. Embodiment (Example of an imaging device in which a pixel including a plurality of photodiodes PD is provided with first separation sections that surround the plurality of photodiodes and a second separation that separates the plurality of photodiodes and respective predetermined electric potentials are applies to the first separation sections and the second separation)
2. Modification Example 1 (Another example of a configuration of an imaging device)
3. Modification Example 2 (Example of a planar configuration)
4. Other Modification Examples (Examples of a stacked structure of a first substrate, a second substrate, and a third substrate)
5. Application Example (Imaging System)
6. Practical Application Examples

### 1. EMBODIMENT

### [Functional Configuration of Imaging Device]

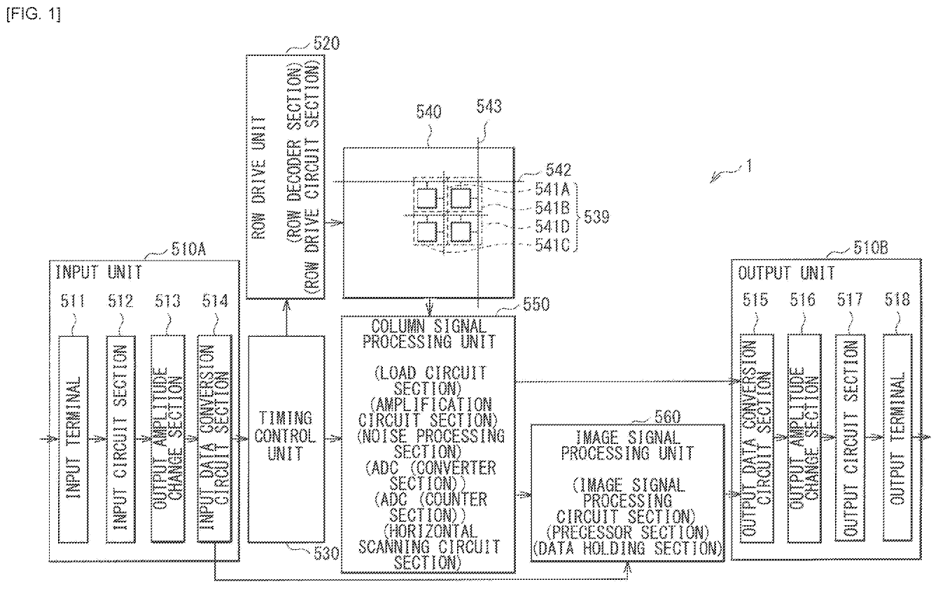

FIG. 1 is a block diagram illustrating an example of a functional configuration of an imaging device (imaging device 1) according to an embodiment of the present disclosure.

The imaging device 1 in FIG. 1 includes, for example, an input unit 510A, a row drive unit 520, a timing control unit 530, a pixel array unit 540, a column signal processing unit 550, an image signal processing unit 560, and an output unit 510B.

In the pixel array unit 540, pixels 541 are repeatedly disposed in an array. More specifically, a unit cell 539 including a plurality of pixels serves as a repeating unit. These unit cells 539 are repeatedly disposed in an array having a row direction and a column direction. It is to be noted that this specification sometimes refers to the row direction as an H direction and refers to the column direction orthogonal to the row direction as a V direction for the sake of convenience. In the example of FIG. 1, the one unit cell 539 includes, for example, four pixels (pixels 541A, 541B, 541C, and 541D).

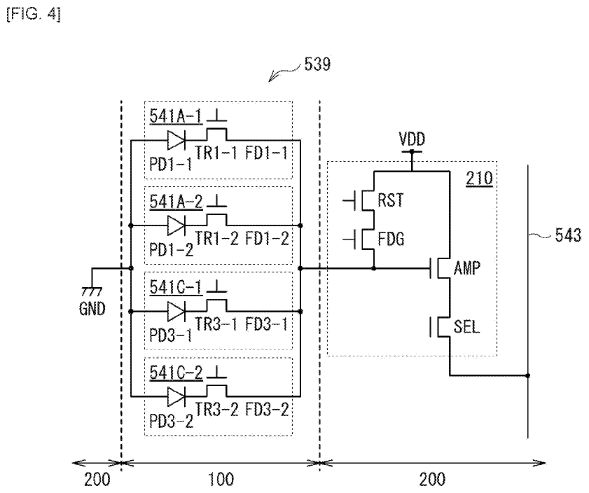

The pixel array unit 540 is provided with a plurality of row drive signal lines 542 and a plurality of vertical signal lines (column readout lines) 543 along with the pixels 541A, 541B, 541C, and 541D. Each of the row drive signal lines 542 drives the pixels 541 included in each of the plurality of unit cells 539 arranged side by side in the row direction in the pixel array unit 540. The respective pixels arranged side by side in the row direction in the unit cell 539 are driven. Although described in detail below with reference to FIG. 4, the unit cell 539 is provided with a plurality of transistors. To drive the plurality of these respective transistors, the plurality of row drive signal lines 542 is coupled to the one unit cell 539. The unit cell 539 is coupled to the vertical signal line (column readout line) 543. A pixel signal is read out from each of the pixels 541A, 541B, 541C, and 541D included in the unit cell 539 through the vertical signal line (column readout line) 543.

The row drive unit 520 includes, for example, a row address control section or a row decoder section that determines the position of a row in which pixels are driven and a row drive circuit section that generates signals for driving the pixels 541A, 541B, 541C, and 541D.

The column signal processing unit 550 is coupled, for example, to the vertical signal line 543. The column signal processing unit 550 includes a load circuit section that forms a source follower circuit with the pixels 541A, 541B, 541C, and 541D (unit cell 539). The column signal processing unit 550 may include an amplification circuit section that amplifies a signal read out from the unit cell 539 through the vertical signal line 543. The column signal processing unit 550 may include a noise processing section. For example, the noise processing section removes the noise level of the system from a signal read out from the unit cell 539 as a result of photoelectric conversion.

The column signal processing unit 550 includes, for example, an analog digital converter (ADC). The analog digital converter converts a signal read out from the unit cell 539 or an analog signal subjected to the noise process described above to a digital signal. The ADC includes, for example, a comparator section and a counter section. The comparator section compares an analog signal to be converted and a reference signal to be compared with this. The counter section measures the time necessary for a result of the comparison by the comparator section to be inverted. The column signal processing unit 550 may include a horizontal scanning circuit section that performs control to scan a readout column.

The timing control unit 530 supplies signals each for controlling a timing to the row drive unit 520 and the column signal processing unit 550 on the basis of a reference clock signal or a timing control signal inputted to the device.

The image signal processing unit 560 is a circuit that performs various kinds of signal processing on data obtained as a result of photoelectric conversion or data obtained as a result of an imaging operation by the imaging device 1. The image signal processing unit 560 includes, for example, an image signal processing circuit section and a data holding section. The image signal processing unit 560 may include a processor section.

Examples of signal processing executed by the image signal processing unit 560 include a tone curve correction process of providing a number of tones in a case where imaging data subjected to AD conversion is data obtained by shooting an image of a dark subject and reducing tones in a case where the imaging data is data obtained by shooting an image of a bright subject. In this case, it is preferable to store tone curve characteristic data in advance in the data holding section of the image signal processing unit 560. The tone curve characteristic data pertains to what tone curve is used to correct the tones of the imaging data.

The input unit 510A is for inputting, for example, the reference clock signal, the timing control signal, the characteristic data, and the like described above to the imaging device 1 from the outside of the device. Examples of the timing control signal include a vertical synchronization signal, a horizontal synchronization signal, and the like. The characteristic data is stored, for example, in the data holding section of the image signal processing unit 560. The input unit 510A includes, for example, an input terminal 511, an input circuit section 512, an input amplitude change section 513, an input data conversion circuit section 514, and a power supply section (not illustrated).

The input terminal 511 is an external terminal for inputting data. The input circuit section 512 is for causing a signal inputted to the input terminal 511 to be taken in the imaging device 1. The input amplitude change section 513 changes the amplitude of the signal that has been caused to be taken in by the input circuit section 512 into amplitude that is easy to use inside the imaging device 1. The input data conversion circuit section 514 reorders the data strings of the input data. The input data conversion circuit section 514 includes, for example, a serial parallel conversion circuit. This serial parallel conversion circuit converts a serial signal received as input data to a parallel signal. It is to be noted that the input unit 510A may omit the input amplitude change section 513 and the input data conversion circuit section 514. The power supply section supplies power set at a variety of voltages necessary inside the imaging device 1 on the basis of power supplied from the outside to the imaging device 1.

In a case where the imaging device 1 is coupled to an external memory device, the input unit 510A may be provided with a memory interface circuit that receives data from the external memory device. Examples of the external memory device include a flash memory, SRAM, DRAM, and the like.

The output unit 510B outputs image data to the outside of the device. Examples of this image data include image data shot by the imaging device 1, image data subjected to signal processing by the image signal processing unit 560, and the like. The output unit 510B includes, for example, an output data conversion circuit section 515, an output amplitude change section 516, an output circuit section 517, and an output terminal 518.

The output data conversion circuit section 515 includes, for example, a parallel serial conversion circuit. The output data conversion circuit section 515 converts a parallel signal used inside the imaging device 1 to a serial signal. The output amplitude change section 516 changes the amplitude of a signal used inside the imaging device 1. The signal whose amplitude has been changed is easier to use in the external device coupled to the outside of the imaging device 1. The output circuit section 517 is a circuit that outputs data from the inside of the imaging device 1 to the outside of the device. The output circuit section 517 drives a wiring line outside the imaging device 1. The wiring line is coupled to the output terminal 518. The output terminal 518 outputs data from the imaging device 1 to the outside of the device. The output unit 510B may omit the output data conversion circuit section 515 and the output amplitude change section 516.

In a case where the imaging device 1 is coupled to an external memory device, the output unit 510B may be provided with a memory interface circuit that outputs data to the external memory device. Examples of the external memory device include a flash memory, SRAM, DRAM, and the like.

### [Schematic Configuration of Imaging Device]

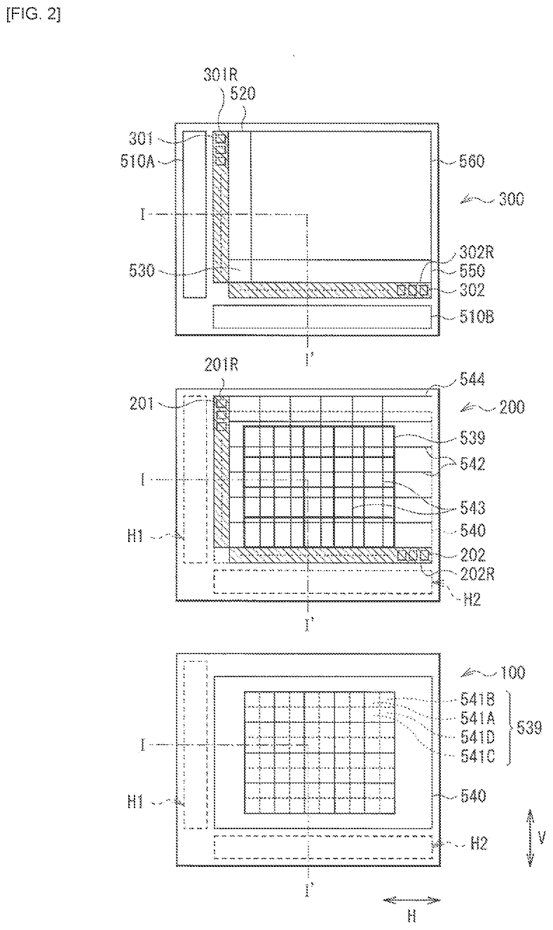

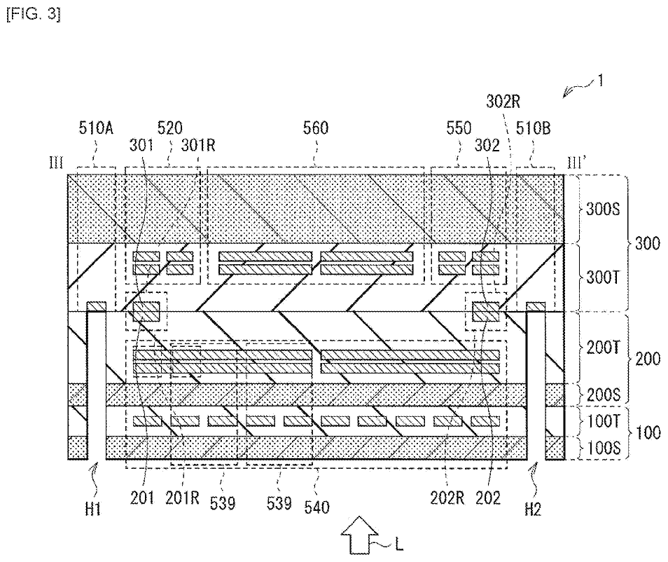

Each of FIGS. 2 and 3 illustrates an example of a schematic configuration of the imaging device 1. The imaging device 1 includes three substrates (a first substrate 100, a second substrate 200, and a third substrate 300). FIG. 2 schematically illustrates respective planar configurations of the first substrate 100, the second substrate 200, and the third substrate 300 and FIG. 3 schematically illustrates a cross-sectional configuration of the first substrate 100, the second substrate 200, and the third substrate 300 that are stacked. FIG. 3 corresponds to a cross-sectional configuration taken along an I-I′ line illustrated in FIG. 2. The imaging device 1 is an imaging device that has a three-dimensional structure in which three substrates (the first substrate 100, the second substrate 200, and the third substrate 300) are bonded together. The first substrate 100 includes a semiconductor layer 100S and a wiring layer 100T. The second substrate 200 includes a semiconductor layer 200S and a wiring layer 200T. The third substrate 300 includes a semiconductor layer 300S and a wiring layer 300T. Here, wiring lines included in the respective substrates of the first substrate 100, the second substrate 200, and the third substrate 300 and interlayer insulating films around the wiring lines are collectively referred to as wiring layers (100T, 200T, and 300T) provided in the respective substrates (the first substrate 100, the second substrate 200, and the third substrate 300) for the sake of convenience. The first substrate 100, the second substrate 200, and the third substrate 300 are stacked in this order. The semiconductor layer 100S, the wiring layer 100T, the semiconductor layer 200S, the wiring layer 200T, the wiring layer 300T, and the semiconductor layer 300S are disposed in this order along the stack direction. Specific configurations of the first substrate 100, the second substrate 200, and the third substrate 300 are described below. An arrow illustrated in FIG. 3 indicates an incidence direction of light L entering the imaging device 1. This specification sometimes refers to the light incidence side of the imaging device 1 as “down”, “lower side”, and “below” and refers to the opposite side to the light incidence side as “up”, “upper side”, and “above” in the following cross-sectional views for the sake of convenience. In addition, this specification sometimes refers to a side of a substrate including a semiconductor layer and a wiring layer closer to the wiring layer as a front surface and refers to a side of the substrate closer to the semiconductor layer as a back surface for the sake of convenience. It is to be noted that the description of the specification is not limited to the wordings described above. The imaging device 1 is, for example, a back-illuminated imaging device that light enters from the back surface side of the first substrate 100 including a photodiode.

The pixel array unit 540 and the unit cell 539 included in the pixel array unit 540 are both configured by using both the first substrate 100 and the second substrate 200. The first substrate 100 is provided with the plurality of pixels 541A, 541B, 541C, and 541D included in the unit cell 539. Each of these pixels 541 includes a photodiode (a photodiode PD described below) and a transfer transistor (a transfer transistor TR described below). The second substrate 200 is provided with a pixel circuit (a pixel circuit 210 described below) included in the unit cell 539. The pixel circuit reads out a pixel signal transferred from the photodiode of each of the pixels 541A, 541B, 541C, and 541D through the transfer transistor or resets the photodiode. This second substrate 200 includes the plurality of row drive signal lines 542 extending in the row direction and the plurality of vertical signal lines 543 extending in the column direction in addition to such a pixel circuit. The second substrate 200 further includes a power supply line 544 extending in the row direction. The third substrate 300 includes, for example, the input unit 510A, the row drive unit 520, the timing control unit 530, the column signal processing unit 550, the image signal processing unit 560, and the output unit 510B. The row drive unit 520 is provided, for example, in a region partially overlapping with the pixel array unit 540 in the stack direction (that is referred to simply as a stack direction below) of the first substrate 100, the second substrate 200, and the third substrate 300. More specifically, the row drive unit 520 is provided in a region overlapping with the region near an end of the pixel array unit 540 in the H direction in the stack direction (FIG. 2). The column signal processing unit 550 is provided, for example, in a region partially overlapping with the pixel array unit 540 in the stack direction. More specifically, the column signal processing unit 550 is provided in a region overlapping with the region near an end of the pixel array unit 540 in the V direction in the stack direction (FIG. 2). Although not illustrated, the input unit 510A and the output unit 510B may be disposed in a portion other than the third substrate 300. For example, the input unit 510A and the output unit 510B may be disposed in the second substrate 200. Alternatively, the back surface (light incidence surface) side of the first substrate 100 may be provided with the input unit 510A and the output unit 510B. It is to be noted that the pixel circuit provided in the second substrate 200 described above is alternatively referred to as a pixel transistor circuit, a pixel transistor group, a pixel transistor, a pixel readout circuit, or a readout circuit in some cases. This specification uses the name of a pixel circuit.

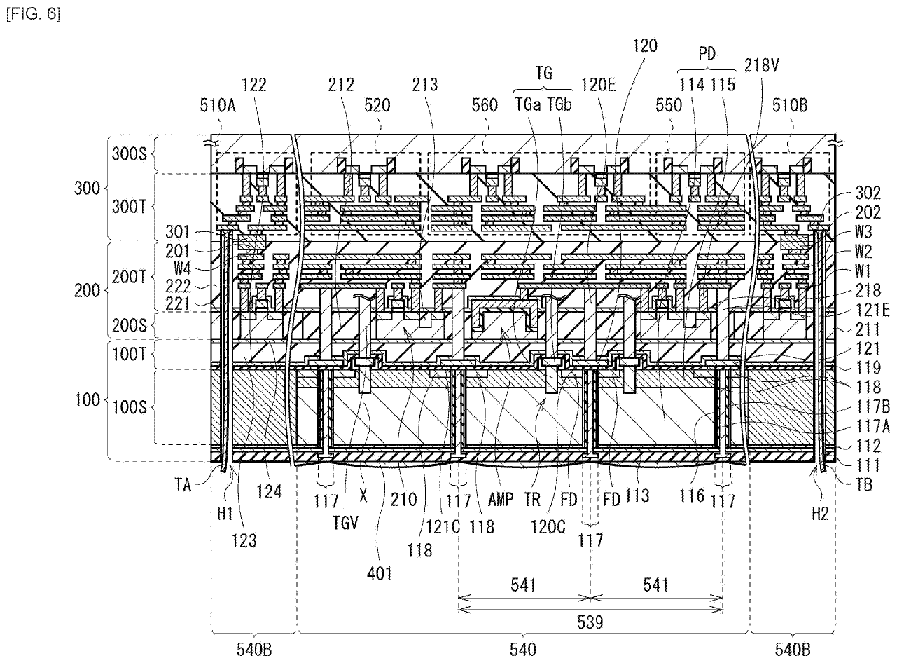

The first substrate 100 and the second substrate 200 are electrically coupled, for example, by through electrodes (through electrodes 120E and 121E, for example, in FIG. 6 described below). The second substrate 200 and the third substrate 300 are electrically coupled, for example, through contact sections 201, 202, 301, and 302. The second substrate 200 is provided with the contact sections 201 and 202 and the third substrate 300 is provided with the contact sections 301 and 302. The contact section 201 of the second substrate 200 is in contact with the contact section 301 of the third substrate 300 and the contact section 202 of the second substrate 200 is in contact with the contact section 302 of the third substrate 300. The second substrate 200 includes a contact region 201R provided with the plurality of contact sections 201 and a contact region 202R provided with the plurality of contact sections 202. The third substrate 300 includes a contact region 301R provided with the plurality of contact sections 301 and a contact region 302R provided with the plurality of contact sections 302. The contact regions 201R and 301R are provided between the pixel array unit 540 and the row drive unit 520 in the stack direction (FIG. 3). In other words, the contact regions 201R and 301R are provided, for example, in the region in which the row drive unit 520 (third substrate 300) and the pixel array unit 540 (second substrate 200) overlap with each other in the stack direction or the region near this. Each of the contact regions 201R and 301R is disposed, for example, at an end of such a region in the H direction (FIG. 2). The third substrate 300 is provided, for example, with the contact region 301R at a position overlapping with a portion of the row drive unit 520. Specifically, the third substrate 300 is provided, for example, with the contact region 301R at a position overlapping with an end of the row drive unit 520 in the H direction (FIGS. 2 and 3). The contact sections 201 and 301 couple, for example, the row drive unit 520 provided in the third substrate 300 and the row drive signal line 542 provided in the second substrate 200. The contact sections 201 and 301 may couple, for example, the input unit 510A provided in the third substrate 300 and the power supply line 544 and a reference electric potential line (a reference electric potential line VSS described below). The contact regions 202R and 302R are provided between the pixel array unit 540 and the column signal processing unit 550 in the stack direction (FIG. 3). In other words, the contact regions 202R and 302R are provided, for example, in the region in which the column signal processing unit 550 (third substrate 300) and the pixel array unit 540 (second substrate 200) overlap with each other in the stack direction or the region near this. Each of the contact regions 202R and 302R is disposed, for example, at an end of such a region in the V direction (FIG. 2). The third substrate 300 is provided, for example, with the contact region 301R at a position overlapping with a portion of the column signal processing unit 550. Specifically, the third substrate 300 is provided, for example, with the contact region 301R at a position overlapping with an end of the column signal processing unit 550 in the V direction (FIGS. 2 and 3). The contact sections 202 and 302 are for coupling, for example, pixel signals (signals corresponding to the amount of electric charge generated as a result of photoelectric conversion by the photodiodes) outputted from the plurality of respective unit cells 539 included in the pixel array unit 540 to the column signal processing unit 550 provided in the third substrate 300. The pixel signals are sent from the second substrate 200 to the third substrate 300.

As described above, FIG. 3 is an example of a cross-sectional view of the imaging device 1. The first substrate 100, the second substrate 200, and the third substrate 300 are electrically coupled through the wiring layers 100T, 200T, and 300T. For example, the imaging device 1 includes an electrical coupling section that electrically couples the second substrate 200 and the third substrate 300. Specifically, electrodes each formed by using an electrically conductive material are used to form the contact sections 201, 202, 301, and 302. The electrically conductive material is formed by using, for example, a metal material such as copper (Cu), aluminum (Al), or gold (Au). The contact regions 201R, 202R, 301R, and 302R electrically couple the second substrate and the third substrate, for example, by directly bonding wiring lines formed as electrodes and make it possible to input and/or output signals to and/or from the second substrate 200 and the third substrate 300.

It is possible to provide the electrical coupling section at a desired position. The electrical coupling section electrically couples the second substrate 200 and the third substrate 300. For example, as described in FIG. 3 as the contact regions 201R, 202R, 301R, and 302R, the electrical coupling section may be provided in a region overlapping with the pixel array unit 540 in the stack direction. In addition, the electrical coupling section may be provided in a region that does not overlap with the pixel array unit 540 in the stack direction. Specifically, the electrical coupling section may be provided in a region overlapping with a peripheral portion in the stack direction. The peripheral portion is disposed outside the pixel array unit 540.

The first substrate 100 and the second substrate 200 are provided, for example, with coupling hole sections H1 and H2. The coupling hole sections H1 and H2 extend through the first substrate 100 and the second substrate 200 (FIG. 3). The coupling hole sections H1 and H2 are provided outside the pixel array unit 540 (or the portions each overlapping with the pixel array unit 540) (FIG. 2). For example, the coupling hole section H1 is disposed outside the pixel array unit 540 in the H direction and the coupling hole section H2 is disposed outside the pixel array unit 540 in the V direction. For example, the coupling hole section H1 reaches the input unit 510A provided in the third substrate 300 and the coupling hole section H2 reaches the output unit 510B provided in the third substrate 300. Each of the coupling hole sections H1 and H2 may be hollow or may include an electrically conductive material at least partially. For example, there is a configuration in which a bonding wire is coupled to each of electrodes formed as the input unit 510A and/or the output unit 510B. Alternatively, there is a configuration in which electrodes formed as the input unit 510A and/or the output unit 510B and electrically conductive materials provided in the coupling hole sections H1 and H2 are coupled. The electrically conductive materials provided in the coupling hole sections H1 and H2 may be embedded in portions of the coupling hole sections H1 and H2 or the whole of the coupling hole sections H1 and H2 or the electrically conductive materials may be formed on the side walls of the coupling hole sections H1 and H2.

It is to be noted that FIG. 3 illustrates a structure in which the third substrate 300 is provided with the input unit 510A and the output unit 510B, but this is not limitative. For example, it is also possible to provide the input unit 510A and/or the output unit 510B to the second substrate 200 by sending signals of the third substrate 300 to the second substrate 200 through the wiring layers 200T and 300T. Similarly, it is also possible to provide the input unit 510A and/or the output unit 510B to the first substrate 100 by sending signals of the second substrate 200 to a first substrate 1000 through the wiring layers 100T and 200T.

### [Specific Configuration of Imaging Device]

Each of the pixels 541A, 541B, 541C, and 541D includes a common component. To distinguish the components of the pixels 541A, 541B, 541C, and 541D from each other, the following attaches an identification number 1 to the end of the sign of a component of the pixel 541A, attaches an identification number 2 to the end of the sign of a component of the pixel 541B, attaches an identification number 3 to the end of the sign of a component of the pixel 541C, and attaches an identification number 4 to the end of the sign of a component of the pixel 541D. In a case where there is no need to distinguish the components of the pixels 541A, 541B, 541C, and 541D from each other, the identification numbers at the ends of the signs of the components of the pixels 541A, 541B, 541C, and 541D are omitted.

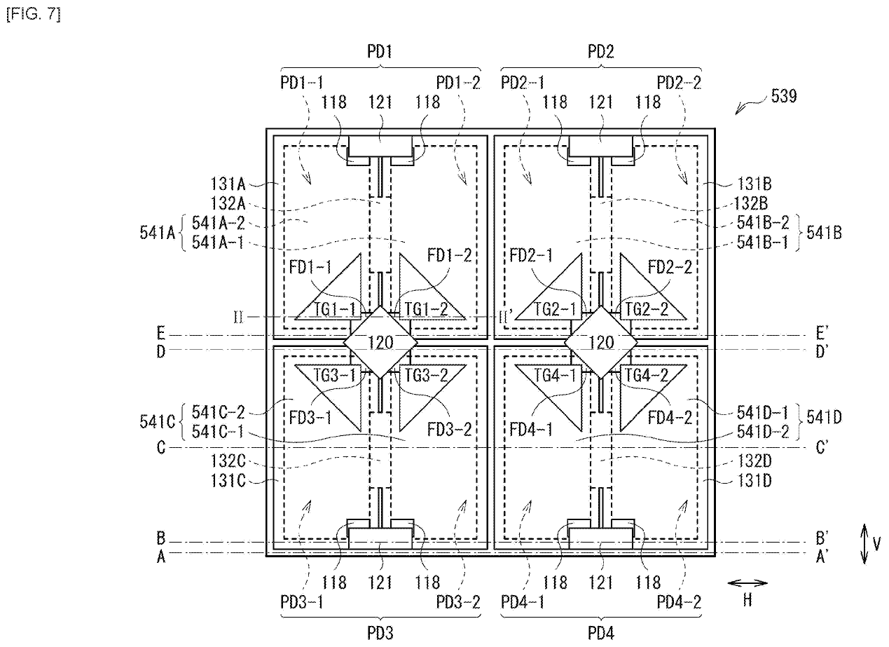

Each of the pixels 541A, 541B, 541C, and 541D according to the present embodiment has a dual-pixel structure in which the plurality of (e.g., two) photodiodes PD (see FIG. 7 described below for PD1-1, PD1-2, PD2-1, PD2-2, PD3-1, PD3-2, PD4-1, and PD4-2) is disposed side by side in the H direction. In other words, two sub-pixels are disposed side by side in the H direction in each of the pixels 541A, 541B, 541C, and 541D. For example, sub-pixels 541A-1 and 541A-2 are disposed side by side in the H direction in the pixel 541A. Sub-pixels 541B-1 and 541B-2 are disposed side by side in the H direction in the pixel 541B. Sub-pixels 541C-1 and 541C-2 are disposed side by side in the H direction in the pixel 541C. Sub-pixels 541D-1 and 541D-2 are disposed side by side in the H direction in the pixel 541D. The unit cell 539 includes four sub-pixels in the row direction and two pixels in the column direction. In the unit cell 539, two pixels (e.g., the pixel 541A and the pixel 541C or the pixel 541B and the pixel 541D) adjacent, for example, in the V direction share one pixel circuit (the pixel circuit 210 in FIG. 3 described below). This pixel circuit 210 is brought into operation in a time division manner to sequentially read out pixel signals from the four sub-pixels (e.g., the sub-pixels 541A-1, 541A-2, 541C-1, and 541C-2) provided in two pixels (e.g., the pixel 541A and the pixel 541C) adjacent in the V direction.

FIG. 4 is an equivalent circuit diagram illustrating an example of a configuration of the unit cell 539. The unit cell 539 includes the plurality of pixels 541, the one pixel circuit 210 coupled to the plurality of these pixels 541, and the vertical signal line 543 coupled to the pixel circuit 210. Specifically, the one pixel circuit 210 is coupled for every two pixels (e.g., the pixel 541A and the pixel 541C or the pixel 541B and the pixel 541C) adjacent, for example, in the V direction as described above. As a configuration of the pixel circuit 210 for the two pixels 541 adjacent in the V direction, the pixel circuits 210 for the pixel 541A and the pixel 541C, and the pixel 541B and the pixel 541C have similar configurations. FIG. 4 describes the pixel circuit 210 for the pixel 541A and the pixel 541C.

The pixel circuit 210 includes, for example, four transistors. Specifically, the pixel circuit 210 includes an amplification transistor AMP, a selection transistor SEL, a reset transistor RST, and an FD conversion gain switching transistor FDG. As described above, the one pixel circuit 210 is brought into operation in a time division manner to cause the unit cell 539 to sequentially output pixel signals of the four respective sub-pixels (e.g., the four sub-pixels 541A-1, 541A-2, 541C-1, and 541C-2 provided in the pixel 541A and the pixel 541C adjacent in the V direction) provided in two adjacent pixels to the vertical signal line 543. The one pixel circuit 210 is coupled to the plurality of pixels 541. A mode in which pixel signals of the plurality of these pixels 541 are outputted from the one pixel circuit 210 in a time division manner is called “the plurality of pixels 541 shares the one pixel circuit 210”.

As described above, each of the pixels 541A, 541B, 541C, and 541D includes, for example, the two photodiodes PD-1 and PD-2 (e.g., the photodiodes PD1-1 and PD1-2 in the pixel 541A), transfer transistors TR-1 and TR-2 (e.g., transfer transistors TR1-1 and TR1-2 in the pixel 541A), and floating diffusions FD-1 and FD-2 (e.g., floating diffusions FD1-1 and FD1-2 in the pixel 541A). The transfer transistors TR-1 and TR-2 are electrically coupled to the photodiodes PD-1 and PD-2, respectively. The floating diffusions FD-1 and FD-2 are electrically coupled to the transfer transistors TR-1 and TR-2, respectively. Each of the photodiodes PD has the cathode electrically coupled to the source of the transfer transistor TR and has the anode electrically coupled to a reference electric potential line (e.g., ground). The photodiode PD photoelectrically converts incident light to generate electric charge corresponding to the amount of received light. The transfer transistor TR is, for example, an n-type CMOS (Complementary Metal Oxide Semiconductor) transistor. The transfer transistor TR has the drain electrically coupled to the floating diffusion FD and has the gate electrically coupled to a drive signal line. This drive signal line is a portion of the plurality of row drive signal lines 542 (see FIG. 1) coupled to the one unit cell 539. The transfer transistor TR transfers the electric charge generated by the photodiode PD to the floating diffusion FD. The floating diffusion FD is an n-type diffusion layer region formed in a p-type semiconductor layer. The floating diffusion FD is an electric charge holding means that temporarily holds the electric charge transferred from the photodiode PD and an electric charge-voltage conversion means that generates a voltage corresponding to the amount of electric charge.

The floating diffusions FD (e.g., the floating diffusion FD1-1 provided in the sub-pixel 541A-1, the floating diffusion FD1-2 provided in the sub-pixel 541A-2, a floating diffusion FD3-1 provided in the sub-pixel 541C-1, and a floating diffusion FD3-2 provided in the sub-pixel 541C-2) provided in the four respective sub-pixels of the two pixels 541 adjacent, for example, in the V direction in the one unit cell 539 are electrically coupled to each other. In addition, the floating diffusions FD are electrically coupled to a gate of the amplification transistor AMP and a source of the FD conversion gain switching transistor FDG. The drain of the FD conversion gain switching transistor FDG is coupled to the source of the reset transistor RST and the gate of the FD conversion gain switching transistor FDG is coupled to a drive signal line. This drive signal line is a portion of the plurality of row drive signal lines 542 coupled to the one unit cell 539. The drain of the reset transistor RST is coupled to a power supply line VDD and the gate of the reset transistor RST is coupled to a drive signal line. This drive signal line is a portion of the plurality of row drive signal lines 542 coupled to the one unit cell 539. The gate of the amplification transistor AMP is coupled to the floating diffusion FD, the drain of the amplification transistor AMP is coupled to the power supply line VDD, and the source of the amplification transistor AMP is coupled to the drain of the selection transistor SEL. The source of the selection transistor SEL is coupled to the vertical signal line 543 and the gate of the selection transistor SEL is coupled to a drive signal line. This drive signal line is a portion of the plurality of row drive signal lines 542 coupled to the one unit cell 539.

In a case where the transfer transistor TR enters an on state, the transfer transistor TR transfers the electric charge of the photodiode PD to the floating diffusion FD. The gate (transfer gate TG) of the transfer transistor TR includes, for example, a so-called vertical electrode and is provided to extend from the front surface of a semiconductor layer (the semiconductor layer 100S in FIG. 6 described below) to the depth of the PD as illustrated in FIG. 6 described below. The reset transistor RST resets the electric potential of the floating diffusion FD to a predetermined electric potential. In a case where the reset transistor RST enters the on state, the reset transistor RST resets the electric potential of the floating diffusion FD to the power supply line VDD. The selection transistor SEL controls the output timing of a pixel signal from the pixel circuit 210. The amplification transistor AMP generates, as a pixel signal, a signal of a voltage corresponding to the level of the electric charge held in the floating diffusion FD. The amplification transistor AMP is coupled to the vertical signal line 543 through the selection transistor SEL. This amplification transistor AMP is included in a source follower in the column signal processing unit 550 along with the load circuit section (see FIG. 1) coupled to the vertical signal line 543. In a case where the selection transistor SEL enters the on state, the amplification transistor AMP outputs the voltage of the floating diffusion FD to the column signal processing unit 550 through the vertical signal line 543. The reset transistor RST, the amplification transistor AMP, and the selection transistor SEL are, for example, N-type CMOS transistors.

The FD conversion gain switching transistor FDG is used to change the gain of electric charge-voltage conversion by the floating diffusion FD. In general, a pixel signal is small in shooting an image in a dark place. In a case where electric charge-voltage conversion is performed on the basis of Q=CV, the floating diffusion FD having larger capacitance (FD capacitance C) results in smaller V that is obtained in a case of conversion to a voltage by the amplification transistor AMP. In contrast, a bright place offers a larger pixel signal. It is therefore not possible for the floating diffusion FD to completely receive the electric charge of the photodiode PD unless the FD capacitance C is large. Further, the FD capacitance C has to be large to prevent V from being too large (i.e., to make V small) in a case of conversion to a voltage by the amplification transistor AMP. Taking these into consideration, in a case where the FD conversion gain switching transistor FDG is turned on, the gate capacitance for the FD conversion gain switching transistor FDG is increased. This causes the whole FD capacitance C to be large. In contrast, in a case where the FD conversion gain switching transistor FDG is turned off, the whole FD capacitance C becomes small. In this way, switching the FD conversion gain switching transistor FDG on and off allows the FD capacitance C to be variable. This makes it possible to switch the conversion efficiency. The FD conversion gain switching transistor FDG is, for example, an N-type CMOS transistor.

It is to be noted that a configuration is also possible in which the FD conversion gain switching transistor FDG is not provided. In this case, for example, the pixel circuit 210 includes, for example, the three transistors of the amplification transistor AMP, the selection transistor SEL, and the reset transistor RST. The pixel circuit 210 includes, for example, at least one of pixel transistors such as the amplification transistor AMP, the selection transistor SEL, the reset transistor RST, and the FD conversion gain switching transistor FDG.

The selection transistor SEL may be provided between the power supply line VDD and the amplification transistor AMP. In this case, the drain of the reset transistor RST is electrically coupled to the power supply line VDD and the drain of the selection transistor SEL. The source of the selection transistor SEL is electrically coupled to the drain of the amplification transistor AMP and the gate of the selection transistor SEL is electrically coupled to the row drive signal line 542 (see FIG. 1). The source of the amplification transistor AMP (the output end of the pixel circuit 210) is electrically coupled to the vertical signal line 543 and the gate of the amplification transistor AMP is electrically coupled to the source of the reset transistor RST. It is to be noted that, although not illustrated, the number of pixels 541 that share the one pixel circuit 210 does not have to be 4. For example, the two or eight pixels 541 may share the one pixel circuit 210.

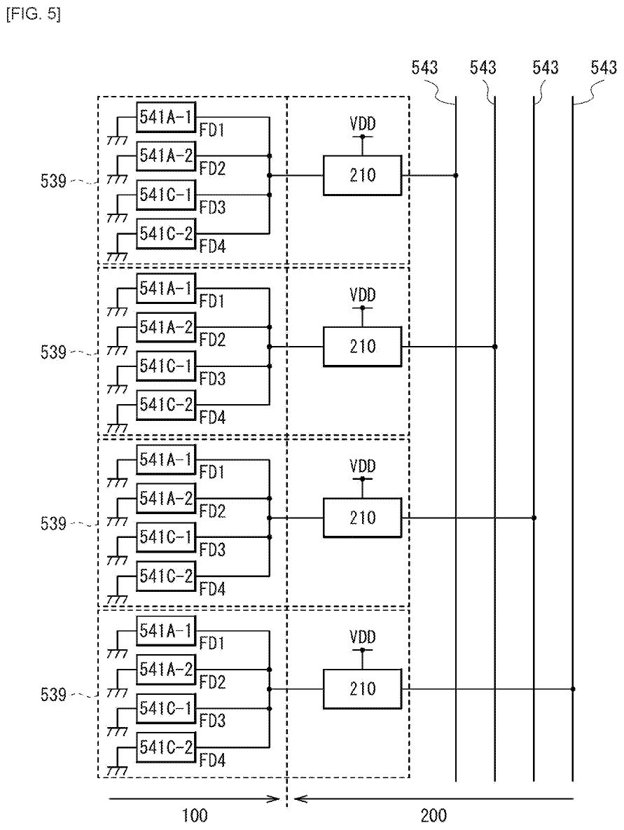

FIG. 5 illustrates an example of a coupling mode between the plurality of unit cells 539 and the vertical signal lines 543. For example, the four unit cells 539 arranged in the column direction are divided into four groups and the vertical signal lines 543 are coupled to these four respective groups. FIG. 5 illustrates an example in which each of the four groups includes the one unit cell 539 for the sake of simpler description, but each of the four groups may also include the plurality of unit cells 539. In this way, in the imaging device 1, the plurality of unit cells 539 arranged in the column direction may be divided into groups each including the one or more unit cells 539. For example, the vertical signal line 543 and the column signal processing unit 550 are coupled to each of these groups. It is possible to read out pixel signals from the respective groups at the same time. Alternatively, in the imaging device 1, the one vertical signal line 543 may be coupled to the plurality of unit cells 539 arranged in the column direction. Pixel signals are then sequentially read out from the plurality of unit cells 539 coupled to the one vertical signal line 543 in a time division manner.

FIG. 6 illustrates an example of a cross-sectional configuration of the first substrate 100, the second substrate 200, and the third substrate 300 of the imaging device 1 in the direction vertical to the principal surface. FIG. 6 schematically illustrates the positional relationship between components for the sake of simplicity and may illustrate a different cross section from the actual cross section. In the imaging device 1, the first substrate 100, the second substrate 200, and the third substrate 300 are stacked in this order. The imaging device 1 further includes a light receiving lens 401 on the back surface side (the light incidence surface side) of the first substrate 100. There may be provided a color filter layer 402 (see, for example FIG. 8) between the light receiving lens 401 and the first substrate 100. The light receiving lens 401 is provided, for example, to each of the pixels 541A, 541B, 541C, and 541D. The imaging device 1 is, for example, a back-illuminated imaging device. The imaging device 1 includes the pixel array unit 540 disposed in the middle portion and a peripheral portion 540B disposed outside the pixel array unit 540.

The first substrate 100 includes an insulating film 111, a fixed electric charge film 112, the semiconductor layer 100S, and the wiring layer 100T in order from the light receiving lens 401 side. The semiconductor layer 100S includes, for example, a silicon substrate. The semiconductor layer 100S includes, for example, a p-well layer 115 in a portion of the front surface (the surface on the wiring layer 100T side) and near it. The semiconductor layer 100S includes an n-type semiconductor region 114 in the other region (a deeper region than the p-well layer 115). For example, these n-type semiconductor region 114 and p-well layer 115 are included in the pn junction photodiode PD. The p-well layer 115 is a p-type semiconductor region.

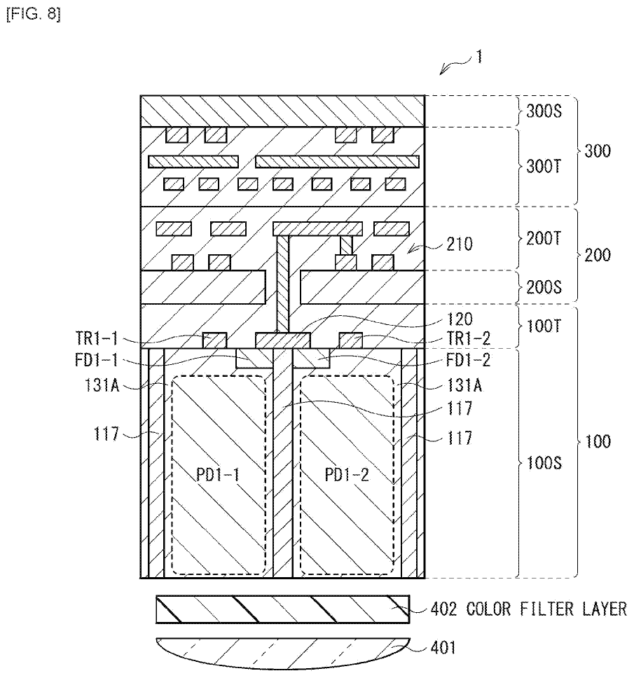

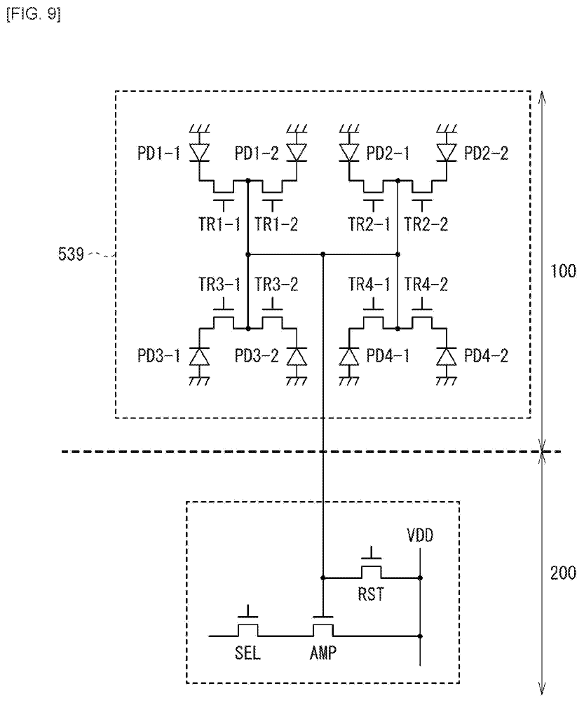

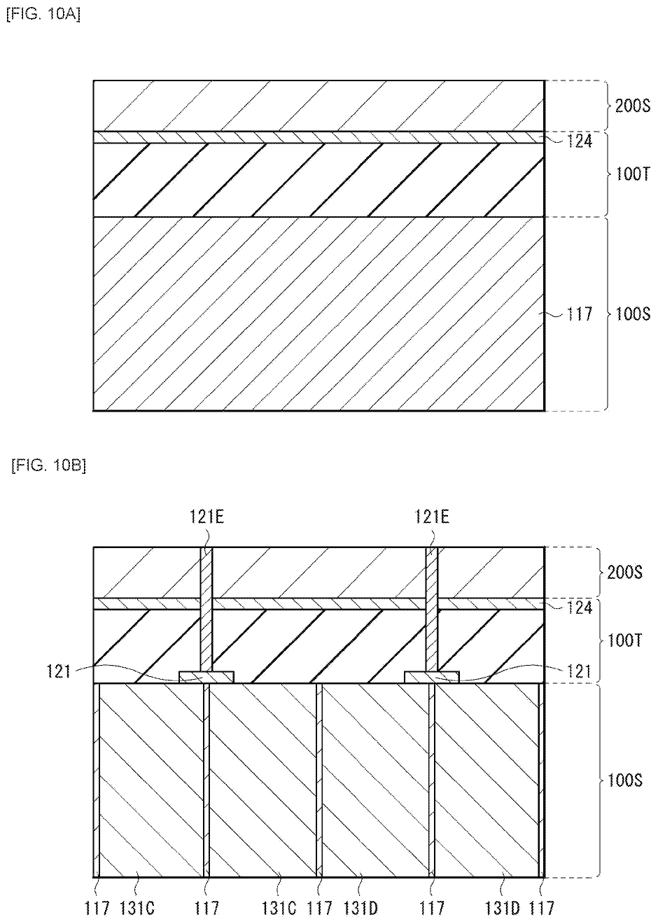

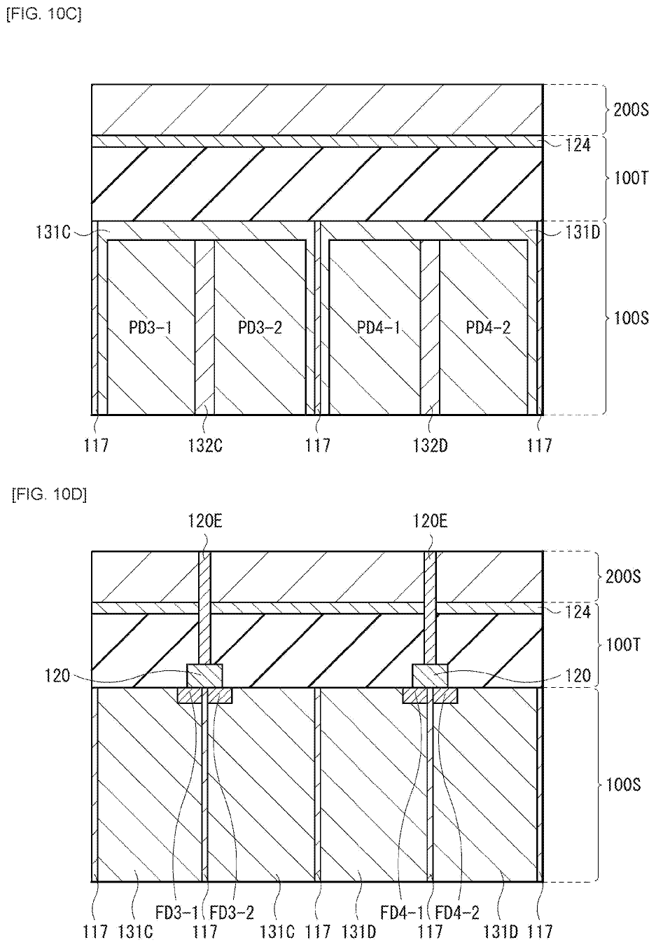

FIG. 7 schematically illustrates an example of a planar configuration of the first substrate 100 according to the present embodiment. FIG. 8 schematically illustrates an example of a cross-sectional configuration of the imaging device 1 taken along an II-IT line illustrated in FIG. 7. FIG. 9 is an equivalent circuit diagram illustrating an example of a configuration of the unit cell 539 illustrated in FIG. 7. FIG. 10A schematically illustrates an example of a cross-sectional configuration of the imaging device 1 taken along an A-A′ line illustrated in FIG. 7. FIG. 10B schematically illustrates an example of a cross-sectional configuration of the imaging device 1 taken along a B-B′ line illustrated in FIG. 7. FIG. 10C schematically illustrates an example of a cross-sectional configuration of the imaging device 1 taken along a C-C′ line illustrated in FIG. 7. FIG. 10D schematically illustrates an example of a cross-sectional configuration of the imaging device 1 taken along a D-D′ line illustrated in FIG. 7. FIG. 10E schematically illustrates an example of a cross-sectional configuration of the imaging device 1 taken along an E-E′ line illustrated in FIG. 7. It is to be noted that FIG. 8 and FIGS. 10A to 10E each omit a portion of the components illustrated in FIG. 6 for the sake of simplicity. The imaging device 1 according to the present embodiment has a dual-pixel structure in which two sub-pixels are disposed side by side, for example, in the H direction, for example, in the one pixel 541 as described above.

Specifically, the pixel 541A includes the two sub-pixels 541A-1 and 541A-2. The sub-pixels 541A-1 and 541A-2 are respectively provided with the photodiodes PD1-1 and PD1-2 as the photodiode PD1. The pixel 541B includes the two sub-pixels 541B-1 and 541B-2. The sub-pixels 541B-1 and 541B-2 are respectively provided with the photodiodes PD2-1 and PD2-2 as the photodiode PD2. The pixel 541C includes the two sub-pixels 541C-1 and 541C-2. The sub-pixels 541C-1 and 541C-2 are respectively provided with the photodiodes PD3-1 and PD3-2 as the photodiode PD3. The pixel 541D includes the two sub-pixels 541D-1 and 541D-2. The sub-pixels 541D-1 and 541D-2 are respectively provided with the photodiodes PD4-1 and PD4-2 as the photodiode PD4.

There are provided first separation sections 131 around the two photodiodes PD provided in each of the pixels 541A, 541B, 541C, and 541D. Further, there is provided a second separation section adjacent to the first separation sections 131 between the two photodiodes PD disposed side by side in each of the pixels 541A, 541B, 541C, and 541D. In other words, the second separation section 132 is provided between the first separation sections 131 vertically extending between the two adjacent photodiodes PD in each of the pixels 541A, 541B, 541C, and 541D in the V direction from regions around the two photodiodes PD. Specifically, there are provided first separation sections 131A around the photodiodes PD1-1 and PD1-2 provided in the pixel 541A and there is provided a second separation section 132A between the photodiode PD1-1 and the photodiode PD1-2. There are provided first separation sections 131B around the photodiodes PD2-1 and PD2-2 provided in the pixel 541B and there is provided a second separation section 132B between the photodiode PD2-1 and the photodiode PD2-2. There are provided first separation sections 131C around the photodiodes PD3-1 and PD3-2 provided in the pixel 541C and there is provided a second separation section 132C between the photodiode PD3-1 and the photodiode PD3-2. There are provided first separation sections 131D around the photodiodes PD4-1 and PD4-2 provided in the pixel 541D and there is provided a second separation section 132D between the photodiode PD4-1 and the photodiode PD4-2.

The first separation sections 131 and the second separation section 132 each include, for example, a p-type semiconductor region (p-well). In addition, the first separation sections 131 may be each formed by combining, for example, a fixed electric charge film and an insulating film in a single layer or multiple layers. It is sufficient if the second separation section 132 is more similar to a p-type semiconductor than at least at a center of the photodiode PD. An electric potential corresponding to electric potentials of the first separation sections 131 is applied to the second separation section 132. For example, each of the pixels 541A, 541B, 541C, and 541D is provided with a VSS contact region 118 in the first separation section 131 for each of the sub-pixels as illustrated in FIG. 7. There is provided a pad section 121 on the VSS contact regions 118. The pad section 121 is shared between the sub-pixels. The VSS contact regions 118 are described below. In the present embodiment, an electric potential of the semiconductor layer 100S below the transfer gate TG (that is referred to as an electric potential below the transfer gate TG below) and electric potentials of the first separation sections 131 are controlled to indirectly control an electric potential of the second separation section 132. Specifically, respective electric potentials are individually applied through the pad sections 121 to the photodiodes PD1, PD2, PD3, and PD4 and the first separation sections 131A, 131B, 131C, and 131D provided around the photodiodes PD1, PD2, PD3, and PD4. This applies desired electric potentials to the second separation sections 132A, 132B, 132C, and 132D respectively provided in the pixels 541A, 541B, 541C, and 541D.

The floating diffusion FD and the VSS contact region 118 are provided near the front surface of the semiconductor layer 100S. The floating diffusion FD includes an n-type semiconductor region provided in the p-well layer 115. The floating diffusions FD are provided for the respective sub-pixels. The floating diffusions FD provided for the respective sub-pixels are provided close to each other at a middle portion of the two pixels adjacent to each other in the V direction. Specifically, the floating diffusions FD1-1, FD1-2, FD3-1, and FD3-2 provided in the sub-pixels 541A-1, 541A-2, 541C-1, and 541C-2 of the respective two pixels 541A and 541C adjacent in the V direction are provided close to each other at a middle portion of the two adjacent pixels 541A and 541C. The floating diffusions FD2-1, FD2-2, FD4-1, and FD4-2 provided in the sub-pixels 541B-1, 541B-2, 541D-1, and 541D-2 of the respective two pixels 541B and 541D adjacent in the V direction are provided close to each other at a middle portion of the two adjacent pixels 541B and 541D. Although described in detail below, the four floating diffusions FD that are close to each other for every two pixels adjacent in the V direction described above are electrically coupled to each other in the first substrate 100 (more specifically, in the wiring layer 100T) through an electrical coupling means (a pad section 120 described below). Further, each of the floating diffusions FD is coupled from the first substrate 100 to the second substrate 200 (more specifically, from the wiring layer 100T to the wiring layer 200T) through an electrical means (the through electrode 120E described below). In the second substrate 200 (more specifically, inside the wiring layer 200T), this electrical means electrically couples each of the floating diffusions FD to the gate of the amplification transistor AMP and the source of the FD conversion gain switching transistor FDG.

The VSS contact region 118 is a region that is electrically coupled to the reference electric potential line VSS. The VSS contact region 118 is disposed away from the floating diffusion FD. The VSS contact region 118 is provided, for example, for each of the sub-pixels of each of the pixels 541A, 541B, 541C, and 541D. Specifically, the sub-pixels 541A-1, 541A-2, 541C-1, and 541C-2 of the two pixels 541A and 541C adjacent in the V direction respectively have the floating diffusions FD1-1, FD1-2, FD3-1, and FD3-2 disposed at ends in the V direction. The sub-pixels 541A-1, 541A-2, 541C-1, and 541C-2 have the respective VSS contact regions 118 disposed at other ends. The sub-pixels 541B-1, 541B-2, 541D-1, and 541D-2 of the two pixels 541B and 541D adjacent in the V direction respectively have the floating diffusions FD2-1, FD2-2, FD4-1, and FD4-2 disposed at ends in the V direction. The sub-pixels 541B-1, 541B-2, 541D-1, and 541D-2 have the respective VSS contact regions 118 disposed at other ends. The VSS contact region 118 includes, for example, a p-type semiconductor region. The VSS contact region 118 is coupled, for example, to a ground electric potential or a fixed electric potential. This supplies the semiconductor layer 100S with a reference electric potential.

The first substrate 100 is provided with the transfer transistor TR along with the photodiode PD, the floating diffusion FD, and the VSS contact region 118. In the present embodiment, this photodiode PD, this floating diffusion FD, this VSS contact region 118, and this transfer transistor TR are provided for each of the sub-pixels as described above. The transfer transistor TR is provided on the front surface side (the opposite side to the light incidence surface side or the second substrate 200 side) of the semiconductor layer 100S for each of the sub-pixels of each of the pixels 541A, 541B, 541C, and 541D. The transfer transistor TR includes the transfer gate TG. The transfer gate TG includes, for example, a horizontal portion TGb opposed to the front surface of the semiconductor layer 100S and a vertical portion TGa provided in the semiconductor layer 100S (FIG. 6). The vertical portion TGa extends in the thickness direction of the semiconductor layer 100S. An end of the vertical portion TGa is in contact with the horizontal portion TGb and the other end is provided in the n-type semiconductor region 114. The transfer transistor TR includes such a vertical transistor. This causes pixel signals to experience deficient transfer less frequently and makes it possible to increase the readout efficiency of pixel signals.

The semiconductor layer 100S is provided with a pixel separation section 117 that separates the pixels 541A, 541B, 541C, and 541D from each other. The pixel separation section 117 is formed to extend in the normal direction of the semiconductor layer 100S (the direction vertical to the front surface of the semiconductor layer 100S). The pixel separation section 117 is provided to partition the pixels 541A, 541B, 541C, and 541D from each other. The pixel separation section 117 has, for example, a planar lattice shape. The pixel separation section 117 further extends from a periphery of the pixel 541 to the second separation section 132 to separate the sub-pixels. For example, the pixel separation section 117 electrically and optically separates the pixels 541A, 541B, 541C, and 541D from each other. Additionally, the pixel separation section 117 electrically and optically separates the two sub-pixels provided in each of the pixels 541A, 541B, 541C, and 541D. The pixel separation section 117 includes, for example, a light shielding film 117A and an insulating film 117B. For example, tungsten (W) or the like is used for the light shielding film 117A. The insulating film 117B is provided between the light shielding film 117A and the p-well layer 115 or the n-type semiconductor region 114. The insulating film 117B includes, for example, silicon oxide (SiO). The pixel separation section 117 has, for example, an FTI (Full Trench Isolation) structure and penetrates the semiconductor layer 100S. Although not illustrated, the pixel separation section 117 provided between the two sub-pixels provided in each of the pixels 541A, 541B, 541C, and 541D is not limited to the FTI structure in which the semiconductor layer 100S is penetrated. For example, the pixel separation section 117 may have a DTI (Deep Trench Isolation) structure in which the semiconductor layer 100S is not penetrated. The pixel separation section 117 between sub-pixels in that case extends in the normal direction of the semiconductor layer 100S and is formed in a portion of the regions of the semiconductor layer 100S.

The semiconductor layer 100S is provided, for example, with a first pinning region 113 and a second pinning region 116. The first pinning region 113 is provided near the back surface of the semiconductor layer 100S and disposed between the n-type semiconductor region 114 and the fixed electric charge film 112. The second pinning region 116 is provided on the side surface of the pixel separation section 117. Specifically, the second pinning region 116 is provided between the pixel separation section 117 and the p-well layer 115 or the n-type semiconductor region 114. The second pinning region 116 corresponds to the first separation section 131 described above. The first pinning region 113 and the second pinning region 116 each include, for example, a p-type semiconductor region.

The fixed electric charge film 112 having negative fixed electric charge is provided between the semiconductor layer 100S and the insulating film 111. The electric field induced by the fixed electric charge film 112 forms the first pinning region 113 of a hole accumulation layer at the interface on the light receiving surface (back surface) side of the semiconductor layer 100S. This suppresses the generation of dark currents caused by the interface level on the light receiving surface side of the semiconductor layer 100S. The fixed electric charge film 112 is formed by using, for example, an insulating film having negative fixed electric charge. Examples of a material of this insulating film having negative fixed electric charge include hafnium oxide, zircon oxide, aluminum oxide, titanium oxide, or tantalum oxide.

The light shielding film 117A is provided between the fixed electric charge film 112 and the insulating film 111. This light shielding film 117A may be provided to be continuous with the light shielding film 117A included in the pixel separation section 117. This light shielding film 117A between the fixed electric charge film 112 and the insulating film 111 is selectively provided, for example, at a position opposed to the pixel separation section 117 in the semiconductor layer 100S. The insulating film 111 is provided to cover this light shielding film 117A. The insulating film 111 includes, for example, silicon oxide.

The wiring layer 100T provided between the semiconductor layer 100S and the second substrate 200 includes an interlayer insulating film 119, the pad sections 120 and 121, a passivation film 122, an interlayer insulating film 123, and a bonding film 124 in this order from the semiconductor layer 100S side. The horizontal portion TGb of the transfer gate TG is provided, for example, in this wiring layer 100T. The interlayer insulating film 119 is provided over the whole of the front surface of the semiconductor layer 100S and is in contact with the semiconductor layer 100S. The interlayer insulating film 119 includes, for example, a silicon oxide film. It is to be noted that the wiring layer 100T is not limited to the configuration described above, but it is sufficient if the wiring layer 100T has a configuration in which a wiring line and an insulating film are included.

Each of the pad sections 120 and 121 is provided in a selective region on the interlayer insulating film 119. The pad section 120 is for coupling, for example, the floating diffusions FD1-1, FD1-2, FD3-1, and FD3-2 to each other. The floating diffusions FD1-1, FD1-2, FD3-1, and FD3-2 are respectively provided for the sub-pixels 541A-1, 541A-2, 541C-1, and 541C-2 of the respective pixels 541A and 541C. In addition, the pad section 120 is for coupling, for example, the floating diffusions FD2-1, FD2-2, FD4-1, and FD4-2 to each other. The floating diffusions FD2-1, FD2-2, FD4-1, and FD4-2 are respectively provided for the sub-pixels 541B-1, 541B-2, 541D-1, and 541D-2 of the respective pixels 541B and 541D. The pad section 120 is disposed, for example, at the middle portion of the two pixels adjacent in the V direction in a plan view (FIG. 7). This pad section 120 is provided across the two pixels adjacent in the V direction. The pad section 120 is disposed to overlap with at least portions of the four respective floating diffusions FD provided close to each other at the middle portion of the two pixels (FIG. 7). The interlayer insulating film 119 is provided with a coupling via 120C for electrically coupling the pad section 120 and the four floating diffusions FD. The coupling via 120C is provided for each of the sub-pixels of each of the pixels 541A, 541B, 541C, and 541D. For example, the coupling via 120C is filled with a portion of the pad section 120. This electrically couples the pad section 120 and the floating diffusions FD1-1, FD1-2, FD3-1, and FD3-2 respectively provided for the sub-pixels 541A-1, 541A-2, 541C-1, and 541C-2 of the respective pixels 541A and 541C adjacent, for example, in the V direction.

The pad section 121 is for coupling the plurality of VSS contact regions 118 to each other. For example, the VSS contact regions 118 provided in the two respective sub-pixels provided in each of the pixels 541A, 541B, 541C, and 541D are electrically coupled by the pad section 121. Specifically, the pad section 121 is provided across the two sub-pixels. The pad section 121 is disposed to overlap with at least portions of the VSS contact regions 118 provided in the two respective sub-pixels. The interlayer insulating film 119 is provided with a coupling via 121C for electrically coupling the pad section 121 and the VSS contact region 118. The coupling via 121C is provided for each of the sub-pixels of each of the pixels 541A, 541B, 541C, and 541D. For example, the coupling via 121C is filled with a portion of the pad section 121. This electrically couples the pad section 121 and the VSS contact regions 118 provided, for example, in the respective sub-pixels 541A-1 and 541A-2 of the pixel 541A. For example, the pad section 120 and the pad section 121 of each of the plurality of pixels 541 arranged in the V direction are disposed at substantially the same position in the H direction.

Providing the pad section 120 allows the whole of the chip to decrease wiring lines for coupling to the respective floating diffusions FD to the pixel circuit 210 (e.g., the gate electrode of the amplification transistor AMP). Similarly, providing the pad section 121 allows the whole of the chip to decrease wiring lines each of which supplies an electric potential to each of the VSS contact regions 118. This makes it possible to decrease the whole of the chip in area, suppress electrical interference between wiring lines in miniaturized pixels, and/or decrease cost by decreasing the number of parts, for example.

It is possible to provide the pad sections 120 and 121 at desired positions in the first substrate 100 and the second substrate 200. Specifically, it is possible to provide the pad sections 120 and 121 in any of the wiring layer 100T and an insulating region 212 of the semiconductor layer 200S. In a case where the pad sections 120 and 121 are provided in the wiring layer 100T, the pad sections 120 and 121 may be in direct contact with the semiconductor layer 100S. Specifically, each of the pad sections 120 and 121 may be configured to be directly coupled to at least a portion of the floating diffusion FD and/or a portion of the VSS contact region 118. In addition, a configuration may be adopted in which the respective coupling vias 120C and 121C are provided from the floating diffusion FD and/or the VSS contact region 118 coupled to each of the pad sections 120 and 121 and the pad sections 120 and 121 are provided at desired positions in the wiring layer 100T and the insulating region 212 of the semiconductor layer 200S.

In particular, in a case where the pad sections 120 and 121 are provided in the wiring layer 100T, it is possible to decrease wiring lines that are coupled to the floating diffusion FD and/or the VSS contact region 118 in the insulating region 212 of the semiconductor layer 200S. This makes it possible to decrease the area of the insulating region 212 for forming a through wiring line for coupling from the floating diffusion FD to the pixel circuit 210 in the second substrate 200 in which the pixel circuit 210 is formed. It is thus possible to secure large area for the second substrate 200 where the pixel circuit 210 is formed. Securing the area of the pixel circuit 210 makes it possible to form a large pixel transistor and contribute to an increase in image quality by reducing noise, for example.

In particular, in a case where an FTI structure is used for the pixel separation section 117 and a dual-pixel structure is further used in which each of the pixels 541 includes a plurality of sub-pixels, it is preferable to provide the floating diffusion FD and/or the VSS contact region 118 for each of the sub-pixels of each of the pixels 541. The use of the configuration of the pad sections 120 and 121 makes it possible to considerably decrease wiring lines that couple the first substrate 100 and the second substrate 200.

Each of the pad sections 120 and 121 includes, for example, polysilicon (Poly Si). More specifically, each of the pad sections 120 and 121 includes doped polysilicon to which an impurity is added. It is preferable that each of the pad sections 120 and 121 include an electrically conductive material having high heat resistance such as polysilicon, tungsten (W), titanium (Ti), and titanium nitride (TiN). This makes it possible to form the pixel circuit 210 after the semiconductor layer 200S of the second substrate 200 is bonded to the first substrate 100.

The passivation film 122 is provided, for example, over the whole of the front surface of the semiconductor layer 100S to cover the pad sections 120 and 121 (FIG. 6). The passivation film 122 includes, for example, a silicon nitride (SiN) film. The interlayer insulating film 123 covers the pad sections 120 and 121 with the passivation film 122 interposed in between. This interlayer insulating film 123 is provided over the whole of the front surface of the semiconductor layer 100S. The interlayer insulating film 123 includes, for example, a silicon oxide (SiO) film. The bonding film 124 is provided on the bonding surface between the first substrate 100 (specifically, the wiring layer 100T) and the second substrate 200. In other words, the bonding film 124 is in contact with the second substrate 200. This bonding film 124 is provided over the whole of the principal surface of the first substrate 100. The bonding film 124 includes, for example, a silicon nitride film or a silicon oxide film.

The light receiving lens 401 is opposed to the semiconductor layer 100S, for example, with the fixed electric charge film 112 and the insulating film 111 interposed in between. The light receiving lens 401 is provided, for example, at a position opposed to each of the pixels 541A, 541B, 541C, and 541D.

The second substrate 200 includes the semiconductor layer 200S and the wiring layer 200T in this order from the first substrate 100 side. The semiconductor layer 200S includes a silicon substrate. The semiconductor layer 200S is provided with a well region 211 in the thickness direction. The well region 211 is, for example, a p-type semiconductor region. The second substrate 200 is provided with the pixel circuit 210. The pixel circuit 210 is disposed for every two pixels adjacent to each other, for example, in the V direction in the unit cell 539. This pixel circuit 210 is provided, for example, on the front surface side (the wiring layer 200T side) of the semiconductor layer 200S. In the imaging device 1, the second substrate 200 is bonded to the first substrate 100 to cause the back surface side (the semiconductor layer 200S side) of the second substrate 200 to be opposed to the front surface side (the wiring layer 100T side) of the first substrate 100. In other words, the second substrate 200 is bonded to the first substrate 100 face to back.

The second substrate 200 is provided with the insulating region 212 that divides the semiconductor layer 200S and an element separation region 213 provided in a portion of the semiconductor layer 200S in the thickness direction. For example, the through electrodes 120E and 121E of the two unit cells 539 and the through electrodes TGV are disposed in the insulating region 212. The insulating region 212 is provided between the two pixel circuits 210 adjacent in the H direction. The two unit cells 539 are coupled to these two pixel circuits 210.

The insulating region 212 has substantially the same thickness as the thickness of the semiconductor layer 200S. The semiconductor layer 200S is divided by this insulating region 212. The through electrodes 120E and 121E and the through electrodes TGV are disposed in this insulating region 212. The insulating region 212 includes, for example, silicon oxide.

The through electrodes 120E and 121E are provided to penetrate the insulating region 212 in the thickness direction. The upper ends of the through electrodes 120E and 121E are coupled to wiring lines (the first wiring layer W1, a second wiring layer W2, a third wiring layer W3, and a fourth wiring layer W4 described below) of the wiring layer 200T. These through electrodes 120E and 121E are provided to penetrate the insulating region 212, the bonding film 124, the interlayer insulating film 123, and the passivation film 122. Lower ends of the through electrodes 120E and 121E are coupled to the pad sections 120 and 121. The through electrode 120E is for electrically coupling the pad section 120 and the pixel circuit 210. In other words, the through electrode 120E electrically couples the floating diffusion FD of the first substrate 100 to the pixel circuit 210 of the second substrate 200. The through electrode 121E is for electrically coupling the pad section 121 and the reference electric potential line VSS of the wiring layer 200T. In other words, the through electrode 121E electrically couples the VSS contact region 118 of the first substrate 100 to the reference electric potential line VSS of the second substrate 200.

The through electrode TGV is provided to penetrate the insulating region 212 in the thickness direction. The upper end of the through electrode TGV is coupled to a wiring line of the wiring layer 200T. This through electrode TGV is provided to penetrate the insulating region 212, the bonding film 124, the interlayer insulating film 123, the passivation film 122, and the interlayer insulating film 119. A lower end of the through electrode TGV is coupled to the transfer gate TG. The through electrode TGV like this is for electrically coupling the transfer gate TG (a transfer gate TG1-1, TG1-2, TG2-1, TG2-2, TG3-2, TG3-2, TG4-1, or TG4-2) provided for every two sub-pixels provided in each of the pixels 541A, 541B, 541C, and 541D and a wiring line (a portion of the row drive signal line 542) of the wiring layer 200T. In other words, the through electrodes TGV electrically couple the transfer gates TG of the first substrate 100 to the wiring lines TRG of the second substrate 200 and drive signals are sent to the respective transfer transistors TR (the transfer gates TG1-1, TG1-2, TG2-1, TG2-2, TG3-2, TG3-2, TG4-1, and TG4-2).

The insulating region 212 is a region in which the through electrodes 120E and 121E and the through electrodes TGV described above are provided to be insulated from the semiconductor layer 200S. The through electrodes 120E and 121E and the through electrodes TGV are for electrically coupling the first substrate 100 and the second substrate 200. For example, the through electrodes 120E and 121E and the through electrodes TGV are disposed in the insulating region 212. The insulating region 212 is provided between the two pixel circuits 210 adjacent in the H direction. The through electrodes 120E and 121E are coupled to these two pixel circuits 210. The insulating region 212 is provided, for example, to extend in the V direction.

The element separation region 213 is provided on the front surface side of the semiconductor layer 200S. The element separation region 213 has an STI (Shallow Trench Isolation) structure. In this element separation region 213, the semiconductor layer 200S is dug in the thickness direction (the direction vertical to the principal surface of the second substrate 200) and this dug portion is filled with an insulating film. This insulating film includes, for example, silicon oxide. The element separation region 213 performs element separation between the plurality of transistors included in the pixel circuit 210 in accordance with the layout of the pixel circuit 210. The semiconductor layer 200S (specifically, the well region 211) extends under the element separation region 213 (a deep portion of the semiconductor layer 200S).

The wiring layer 200T includes, for example, a passivation film 221, an interlayer insulating film 222, and a plurality of wiring lines (the first wiring layer W1, the second wiring layer W2, the third wiring layer W3, and the fourth wiring layer W4). The passivation film 221 is, for example, in contact with the front surface of the semiconductor layer 200S and covers the whole of the front surface of the semiconductor layer 200S. This passivation film 221 covers the respective gate electrodes of the selection transistor SEL, the amplification transistor AMP, the reset transistor RST, and the FD conversion gain switching transistor FDG. The interlayer insulating film 222 is provided between the passivation film 221 and the third substrate 300. This interlayer insulating film 222 separates the plurality of wiring lines (the first wiring layer W1, the second wiring layer W2, the third wiring layer W3, and the fourth wiring layer W4). The interlayer insulating film 222 includes, for example, silicon oxide.

The wiring layer 200T is provided, for example, with the first wiring layer W1, the second wiring layer W2, the third wiring layer W3, the fourth wiring layer W4, and the contact sections 201 and 202 in this order from the semiconductor layer 200S side. These are insulated from each other by the interlayer insulating film 222. The interlayer insulating film 222 is provided with a plurality of coupling sections that couples the first wiring layer W1, the second wiring layer W2, the third wiring layer W3, or the fourth wiring layer W4 and the lower layers of them. Each of the coupling sections is a portion obtained by filling the coupling hole provided in the interlayer insulating film 222 with an electrically conductive material. For example, the interlayer insulating film 222 is provided with a coupling section 218V that couples the first wiring layer W1 and a VSS contact region 218 of the semiconductor layer 200S. For example, the pore size of such a coupling section that couples elements of the second substrate 200 is different from the pore size of each of the through electrodes 120E and 121E and the through electrode TGV. Specifically, it is preferable that the pore size of a coupling hole that couples elements of the second substrate 200 be smaller than the pore size of each of the through electrodes 120E and 121E and the through electrode TGV. The following describes the reason for this. The depth of a coupling section (such as the coupling section 218V) provided in the wiring layer 200T is less than the depth of each of the through electrodes 120E and 121E and the through electrode TGV. This makes it easier to fill the coupling hole of a coupling section with an electrically conductive material than the through electrodes 120E and 121E and the through electrode TGV. This coupling section has a smaller pore size than the pore size of each of the through electrodes 120E and 121E and the through electrode TGV, thereby facilitating the imaging device 1 to be miniaturized.

For example, the first wiring layer W1 couples the through electrode 120E and the gate of the amplification transistor AMP and the source (specifically, the coupling hole that reaches the source of the FD conversion gain switching transistor FDG) of the FD conversion gain switching transistor FDG. The first wiring layer W1 couples, for example, the through electrode 121E and the coupling section 218V. This electrically couples the VSS contact region 218 of the semiconductor layer 200S and the VSS contact region 118 of the semiconductor layer 100S.

For example, the third wiring layer W3 includes the wiring lines TRG1, TRG2, TRG3, TRG4, SELL, RSTL, and FDGL extending in the H direction (row direction) (not illustrated). These wiring lines correspond to the plurality of row drive signal lines 542 described with reference to FIG. 4. The wiring lines TRG1, TRG2, TRG3, and TRG4 are for respectively sending drive signals to the transfer gates TG1 (TG1-1 and TG1-2), TG2 (TG2-1 and TG2-2), TG3 (TG3-1 and TG3-2), and TG4 (TG4-1 and TG4-2). The wiring lines TRG1, TRG2, TRG3, and TRG4 are respectively coupled to the transfer gates TG1 (TG1-1 and TG1-2), TG2 (TG2-1 and TG2-2), TG3 (TG3-1 and TG3-2), and TG4 (TG4-1 and TG4-2) through the second wiring layer W2, the first wiring layer W1, and the through electrode 120E. The wiring line SELL, the wiring line RSTL, and the wiring line FDGL are for respectively sending drive signals to the gate of the selection transistor SEL, the gate of the reset transistor RST, and the gate of the FD conversion gain switching transistor FDG. The wiring lines SELL, RSTL, and FDGL are respectively coupled to the respective gates of the selection transistor SEL, the reset transistor RST, and the FD conversion gain switching transistor FDG through the second wiring layer W2, the first wiring layer W1, and the coupling section.

For example, the fourth wiring layer W4 includes the power supply line VDD, the reference electric potential line VSS, and the vertical signal line 543 extending in the V direction (column direction). The power supply line VDD is coupled to the drain of the amplification transistor AMP and the drain of the reset transistor RST through the third wiring layer W3, the second wiring layer W2, the first wiring layer W1, and the coupling section. The reference electric potential line VSS is coupled to the VSS contact region 218 through the third wiring layer W3, the second wiring layer W2, the first wiring layer W1, and the coupling section 218V. In addition, the reference electric potential line VSS is coupled to the VSS contact region 118 of the first substrate 100 through the third wiring layer W3, the second wiring layer W2, the first wiring layer W1, the through electrode 121E, and the pad section 121. The vertical signal line 543 is coupled to the source (Vout) of the selection transistor SEL through the third wiring layer W3, the second wiring layer W2, the first wiring layer W1, and the coupling section.

The contact sections 201 and 202 may be provided at positions overlapping with the pixel array unit 540 in a plan view (e.g., FIG. 3) or may be provided in the peripheral portion 540B outside the pixel array unit 540 (e.g., FIG. 6). The contact sections 201 and 202 are provided on the front surface (the surface on the wiring layer 200T side) of the second substrate 200. Each of the contact sections 201 and 202 includes, for example, a metal material such as Cu (copper) and Al (aluminum). The contact sections 201 and 202 are exposed from the front surface (the surface on the third substrate 300 side) of the wiring layer 200T. Each of the contact sections 201 and 202 is used to electrically couple the second substrate 200 and the third substrate 300 and bond the second substrate 200 and the third substrate 300 together.

FIG. 6 illustrates an example in which the peripheral portion 540B of the second substrate 200 is provided with a peripheral circuit. This peripheral circuit may include a portion of the row drive unit 520, a portion of the column signal processing unit 550, or the like. In addition, as illustrated in FIG. 3, no peripheral circuit is disposed in the peripheral portion 540B of the second substrate 200, but the coupling hole sections H1 and H2 may be disposed near the pixel array unit 540.

The third substrate 300 includes, for example, the wiring layer 300T and the semiconductor layer 300S in this order from the second substrate 200 side. For example, the front surface of the semiconductor layer 300S is provided on the second substrate 200 side. The semiconductor layer 300S includes a silicon substrate. This portion of the semiconductor layer 300S on the front surface side is provided with a circuit. Specifically, the portion of the semiconductor layer 300S on the front surface side is provided, for example, with at least a portion of the input unit 510A, the row drive unit 520, the timing control unit 530, the column signal processing unit 550, the image signal processing unit 560, and the output unit 510B. The wiring layer 300T provided between the semiconductor layer 300S and the second substrate 200 includes, for example, an interlayer insulating film, a plurality of wiring layers separated by this interlayer insulating film, and the contact sections 301 and 302. The contact sections 301 and 302 are exposed from the front surface (the surface on the second substrate 200 side) of the wiring layer 300T. The contact section 301 and the contact section 302 are respectively in contact with the contact section 201 of the second substrate 200 and the contact section 202 of the second substrate 200. Each of the contact sections 301 and 302 is electrically coupled to a circuit (e.g., at least any of the input unit 510A, the row drive unit 520, the timing control unit 530, the column signal processing unit 550, the image signal processing unit 560, and the output unit 510B) formed in the semiconductor layer 300S. Each of the contact sections 301 and 302 includes, for example, a metal material such as Cu (copper) and aluminum (Al). For example, an external terminal TA is coupled to the input unit 510A through the coupling hole section H1 and an external terminal TB is coupled to the output unit 510B through the coupling hole section H2.

### [Operation of Imaging Device]

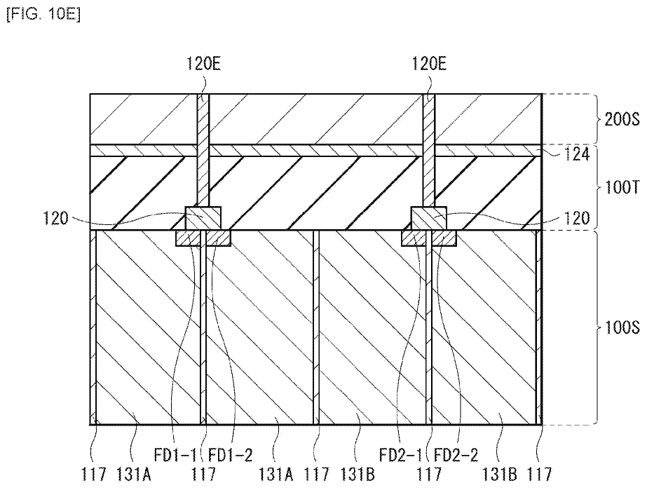

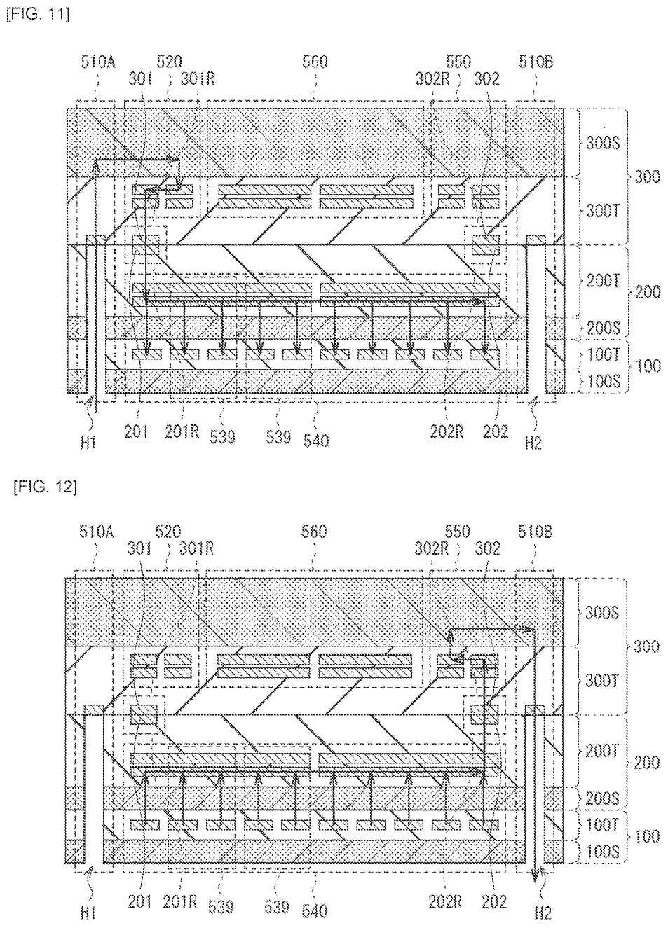

Next, an operation of the imaging device 1 is described with reference to FIGS. 11 and 12. Each of FIGS. 11 and 12 adds arrows to FIG. 3. The arrows indicate the paths of the respective signals. FIG. 11 illustrates the paths of an input signal inputted to the imaging device 1 from the outside, a power supply electric potential, and a reference electric potential as arrows. FIG. 12 illustrates the signal path of a pixel signal outputted from the imaging device 1 to the outside as an arrow. For example, an input signal (e.g., a pixel clock and a synchronization signal) inputted to the imaging device 1 through the input unit 510A is transmitted to the row drive unit 520 of the third substrate 300 and the row drive unit 520 creates a row drive signal. This row drive signal is sent to the second substrate 200 through the contact sections 301 and 201. Further, this row drive signal reaches each of the unit cells 539 of the pixel array unit 540 through the row drive signal line 542 in the wiring layer 200T. Drive signals other than the transfer gates TG among the row drive signals that have reached the unit cells 539 of the second substrate 200 are inputted to the pixel circuit 210 and the respective transistors included in the pixel circuit 210 are driven. Drive signals of the transfer gates TG are inputted to the transfer gates TG1 (TG1-1 and TG1-2), TG2 (TG2-1 and TG2-2), TG3 (TG3-1 and TG3-2), and TG4 (TG4-1 and TG4-2) of the first substrate 100 through the through electrodes TGV and the pixels 541A, 541B, 541C, and 541D are driven (FIG. 11). In addition, a power supply electric potential and a reference electric potential supplied to the input unit 510A (input terminal 511) of the third substrate 300 from the outside of the imaging device 1 are sent to the second substrate 200 through the contact sections 301 and 201 and supplied to the pixel circuit 210 of each of the unit cells 539 through a wiring line in the wiring layer 200T. The reference electric potential is further supplied to each of the pixels 541A, 541B, 541C, and 541D of the first substrate 100 through the through electrode 121E. Meanwhile, the pixel signal electrically converted by each of the pixels 541A, 541B, 541C, and 541D of the first substrate 100 is sent to the pixel circuit 210 of the second substrate 200 for each of the unit cells 539 through the through electrode 120E. The pixel signal based on this pixel signal is sent to the third substrate 300 from the pixel circuit 210 through the vertical signal line 543 and the contact sections 202 and 302. This pixel signal is outputted to the outside through the output unit 510B after processed by the column signal processing unit 550 and the image signal processing unit 560 of the third substrate 300.

### Effects

The imaging device 1 according to the present embodiment is provided with the two photodiodes PD-1 and PD-2 in the one pixel 541. The two photodiodes PD-1 and PD-2 are disposed side by side in a plane of the semiconductor layer 100S. The imaging device 1 according to the present embodiment is provided with the first separation sections 131 and the second separation section 132. The first separation sections 131 surround these two photodiodes PD-1 and PD-2. The second separation section 132 is adjacent to the first separation sections 131 between the photodiode PD-1 and the photodiode PD-2. The electric potential below the transfer gate TG and the electric potentials of the first separation sections 131 are individually controlled to indirectly adjust the electric potential of the second separation section 132. Accordingly, the potentials of the first separation sections and the second separation section are each adjusted as appropriate at a desired value after a wafer is fabricated. The following describes this.

An imaging device having a pixel structure referred to as a so-called dual-pixel structure in which the imaging device includes a plurality of (e.g., two) photoelectric conversion sections in one pixel compares signals obtained from the two photoelectric conversion sections provided in each of a plurality of pixels, thereby performing focus detection for an imaging lens.

Incidentally, the imaging device having a dual-pixel structure adds the signals of the two photoelectric conversion sections in a pixel to acquire a signal for an image for one pixel. Focus detection and imaging request reverse heights from a potential barrier (a potential for separating the same color) that separates the two photoelectric conversion sections provided in a pixel. In other words, it is desirable during focus detection that the potential for separating the same color be high to maintain a separation ratio between the two photoelectric conversion sections. In contrast, it is not possible during imaging to obtain an appropriate image in a case where the two photoelectric conversion sections are different in sensitivity or have different amounts of incident light. It is thus desirable that the potential for separating the same color be low to maintain linearity of addition output characteristics of the two photoelectric conversion sections.

A separation potential (the potential for separating the same color) between a plurality of photoelectric conversion sections provided in one pixel is, however, adjusted by using a dose amount for ion implantation in a typical imaging device having a dual-pixel structure. It is not thus possible to adjust this separation potential after a wafer is fabricated.

As a method of controlling the separation potential, a method has been reported in which a separation region is provided between a plurality of photoelectric conversion sections provided in one pixel and a gate electrode of a potential control switch is provided on this separation region as described above. In a case where the potential for separating the same color is controlled by using the gate electrode in this way, incident light strikes the gate electrode. The incident light striking the gate electrode is reflected and diffracted. This raises a concern about decreasing optical characteristics such as decreasing sensitivity or deteriorated color mixture characteristics.

In contrast, in the present embodiment, the first separation sections 131 are provided around the two photodiodes PD-1 and PD-2 disposed side by side in the one pixel 541. The second separation section 132 is provided at a position adjacent to the first separation sections 131 between the photodiode PD-1 and the photodiode PD-2. Specifically, the second separation section 132 is provided between the first separation sections 131 vertically extending between the photodiode PD-1 and the photodiode PD-2 in the V direction. The electric potential below the transfer gate TG and the electric potentials of the first separation sections 131 are individually controlled to indirectly adjust the electric potential of the second separation section 132. This makes it possible to adjust the potentials of the first separation sections 131 and the second separation section 132 as appropriate at desired values after a wafer is fabricated. Description is given below with reference to working examples.

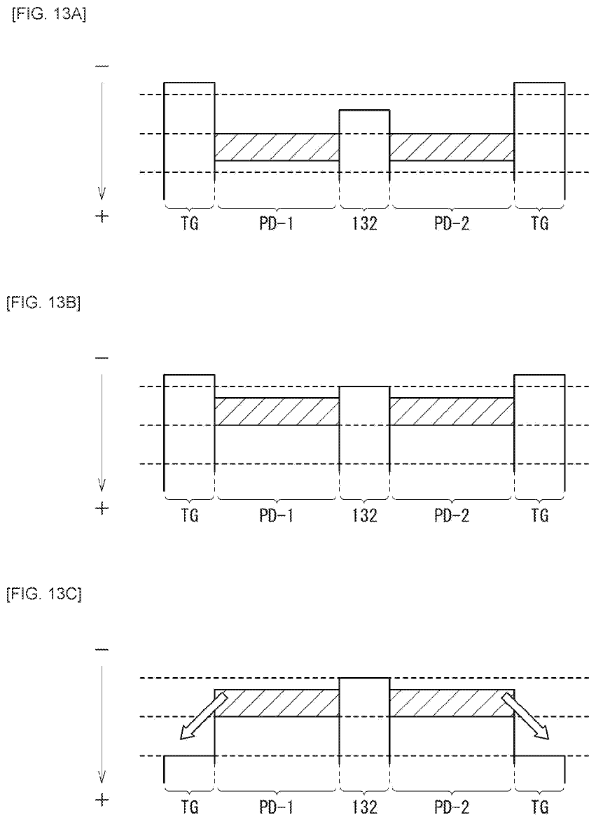

FIGS. 13A to 13C schematically illustrate the potential (electric potential) below the transfer gates TG, and the potentials (electric potentials) of the first separation sections 131 and the second separation section 132 in an electric charge accumulation period (FIG. 13A), a non-selection period (FIG. 13B), and a readout period (FIG. 13C) during autofocusing. FIGS. 14A to 14C schematically illustrate the potential below the transfer gates TG, and the potentials of the first separation sections 131 and the second separation section 132 in an electric charge accumulation period (FIG. 14A), a non-selection period (FIG. 14B), and a readout period (FIG. 14C) during imaging.

In the imaging device 1 according to the present embodiment, voltages are individually applied to the layer below the transfer gates TG and the first separation sections 131 as described above. The first separation sections 131 surround the two photodiodes PD-1 and PD-2 provided in the pixel 541.

For example, the layer below the transfer gates TG has a negative (—) bias (low) and the first separation sections 131 each have a positive (+) bias (high) in the electric charge accumulation period during autofocusing. It is to be noted that the electric potentials of the first separation sections 131 correspond to PD-1 and PD-2 in FIG. 13A (the same applies to the following description). Specifically, as illustrated in FIG. 13A, the electric potential of the second separation section 132>the electric potential below the transfer gates TG is satisfied. In addition, the two photodiodes PD-1 and PD-2 and the second separation section 132 have a great electric potential difference (the electric potentials of the two photodiodes PD-1 and PD-2>>the electric potential of the second separation section 132). This increases saturation charge amounts Qs of the two photodiodes PD-1 and PD-2 and increases the separation ratio. In the non-selection period, for example, the layer below the transfer gates TG has a negative (—) bias (that is substantially the same electric potential as that of the second separation section 132). The first separation sections 131 (PD-1 and PD-2) each have zero biases (FIG. 13B). In the readout period, the first separation sections 131 (PD-1 and PD-2) each have zero biases. The layer below the transfer gates TG has a positive (+) bias (FIG. 13C). This causes signal charge accumulated in each of the two photodiodes PD-1 and PD-2 to be read out from the transfer gate TG.

In contrast, as illustrated in FIG. 14A, the layer below the transfer gates TG has a negative (−) bias and the first separation sections 131 (PD-1 and PD-2) each have a positive (+) bias in the electric charge accumulation period during imaging. Specifically, the two photodiodes PD-1 and PD-2 and the second separation section 132 have a small electric potential difference. In other words, the second separation section 132 and the layer below the transfer gates TG have a great electric potential difference (the electric potential of the second separation section 132>>the electric potential below the transfer gates TG). This facilitates blooming between the photodiodes PD-1 and PD-2 and increases linearity. In the non-selection period, for example, the layer below the transfer gates TG has a negative (—) bias and the first separation sections 131(PD-1 and PD-2) each have zero biases as with autofocusing (FIG. 14B). As with autofocusing, in the readout period, the first separation sections 131 (PD-1 and PD-2) each have zero biases. The layer below the transfer gates TG has a positive (+) bias (FIG. 14C). This causes signal charge accumulated in each of the two photodiodes PD-1 and PD-2 to be read out from the transfer gate TG.

In addition, the potentials of the respective sections in the electric charge accumulation periods, the non-selection periods, and the readout periods during autofocusing and imaging described above are examples. For example, the potential below the transfer gates TG, and the potentials of the first separation sections 131 (PD-1 and PD-2) and the second separation section 132 are adjusted as appropriate in accordance with the amount of incident light and an analog gain. This makes it possible to achieve both the separation ratio and the linearity under a variety of conditions.

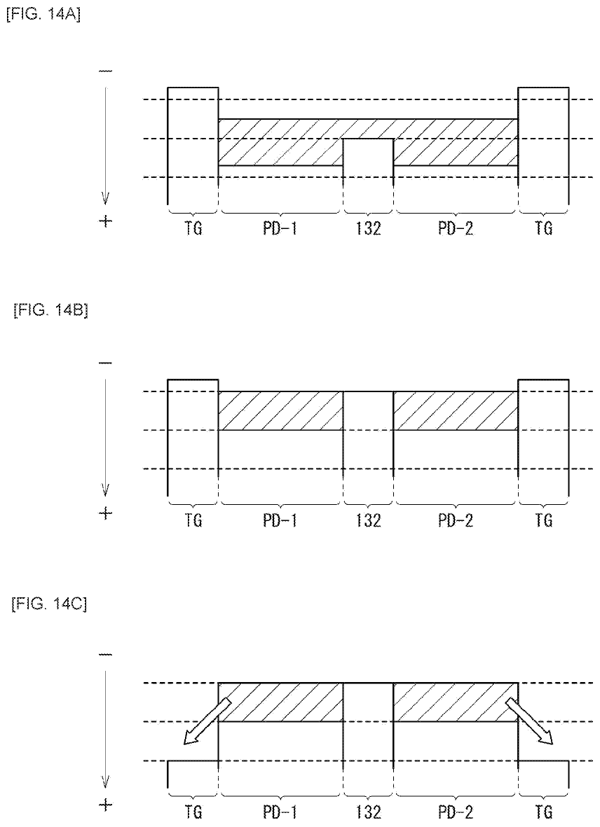

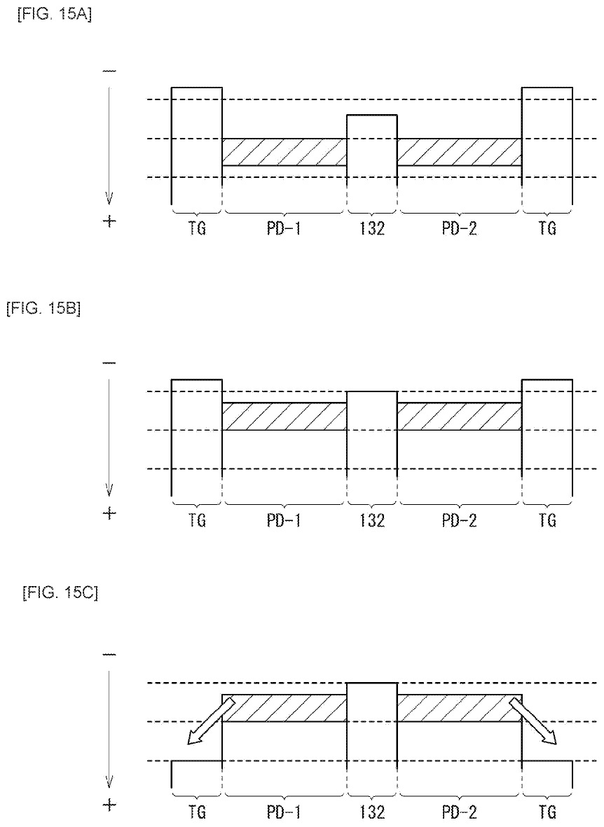

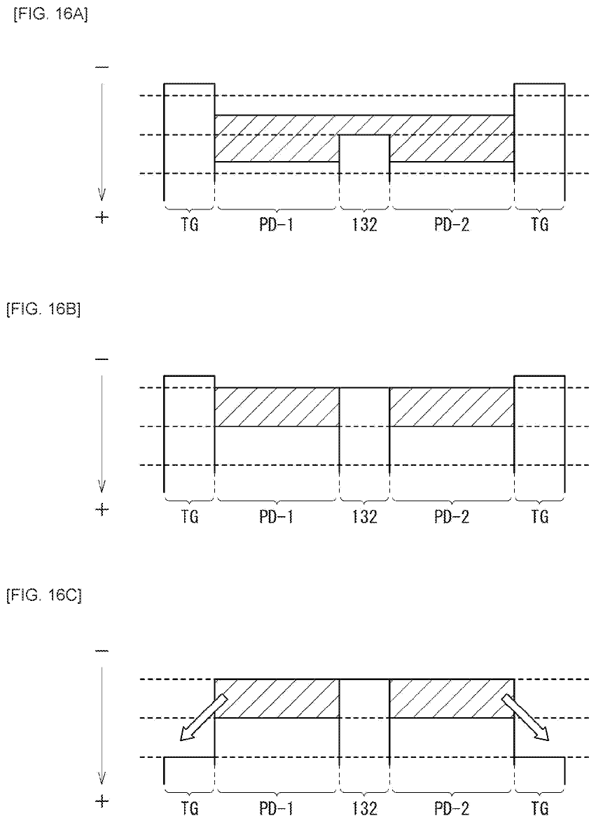

FIGS. 15A to 15C schematically illustrate the potential below the transfer gates TG, and the potentials of the first separation sections 131 and the second separation section 132 in an electric charge accumulation period (FIG. 15A), a non-selection period (FIG. 15B), and a readout period (FIG. 15C) at low illuminance. FIGS. 16A to 16C schematically illustrate the potential below the transfer gates TG, and the potentials of the first separation sections 131 and the second separation section 132 in an electric charge accumulation period (FIG. 16A), a non-selection period (FIG. 16B), and a readout period (FIG. 16C) at high illuminance.

For example, the layer below the transfer gates TG has a negative (—) bias and the first separation sections 131 (PD-1 and PD-2) each have a positive (+) bias in the electric charge accumulation period at low illuminance. Specifically, as illustrated in FIG. 15A, the electric potential of the second separation section 132>the electric potential below the transfer gates TG is satisfied. In addition, the two photodiodes PD-1 and PD-2 and the second separation section 132 have a great electric potential difference (the electric potentials of the two photodiodes PD-1 and PD-2>>the electric potential of the second separation section 132). In contrast, for example, the layer below the transfer gates TG has a negative (—) bias and the first separation sections 131 (PD-1 and PD-2) each have a positive (+) bias in the electric charge accumulation period at high illuminance. Specifically, as illustrated in FIG. 16A, the two photodiodes PD-1 and PD-2 and the second separation section 132 have a small electric potential difference. In other words, the second separation section 132 and the layer below the transfer gates TG have a great electric potential difference (the electric potential of the second separation section 132>>the electric potential below the transfer gates TG). In this way, in the electric charge accumulation period at high illuminance in which the amount of output signals increases, the second separation section 132 has a higher electric potential (set closer to the positive (+) bias side) than at low illuminance. This makes it possible to reduce electric charge leaking to the adjacent pixel 541 and maintain the linearity during imaging.

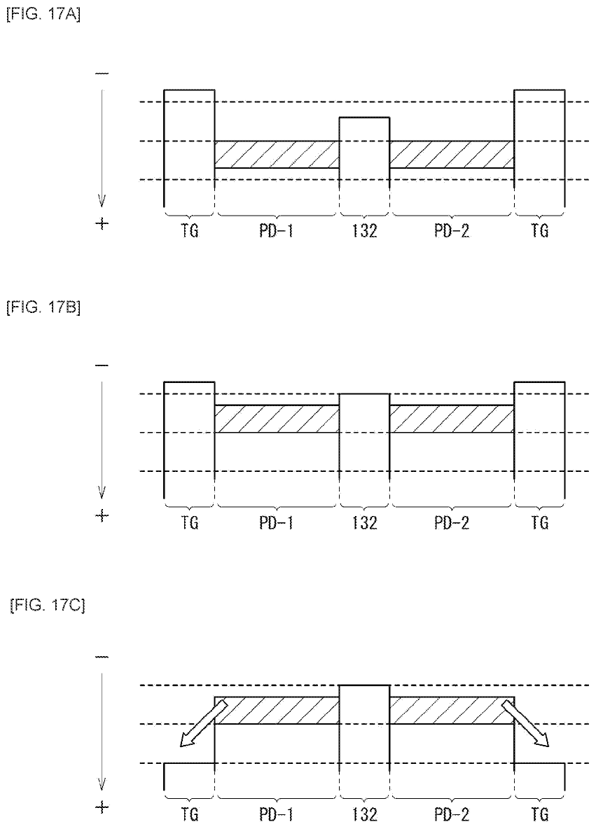

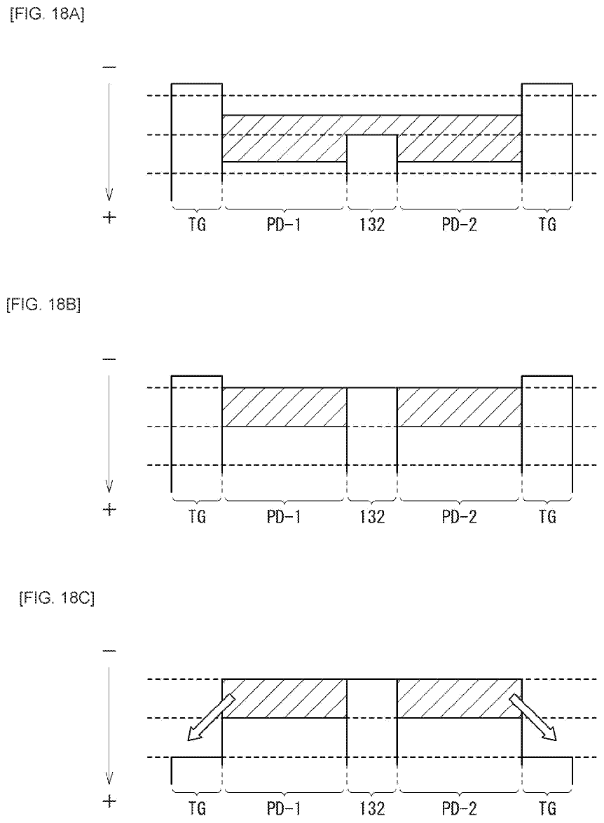

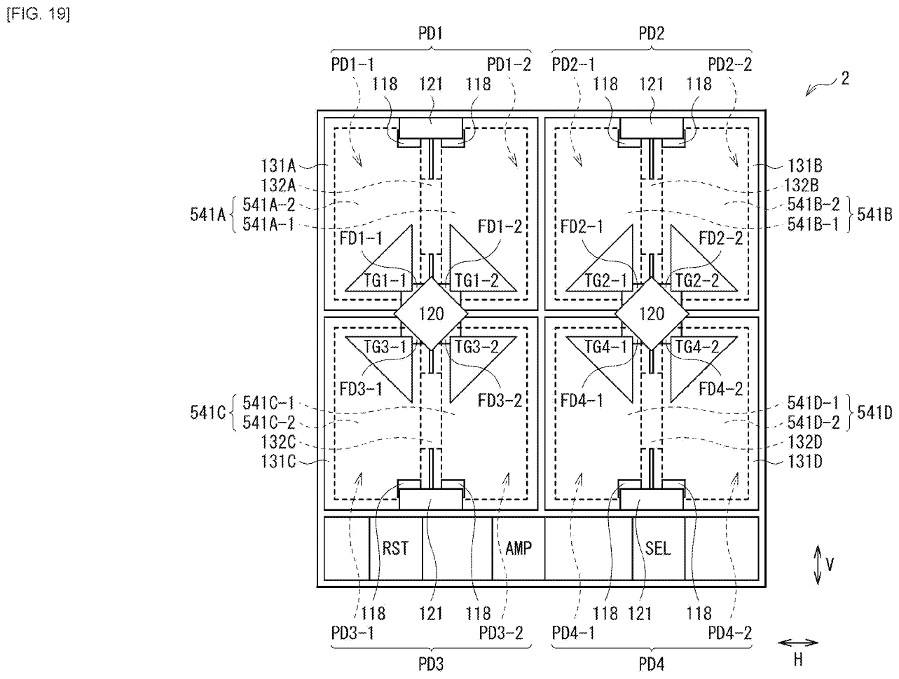

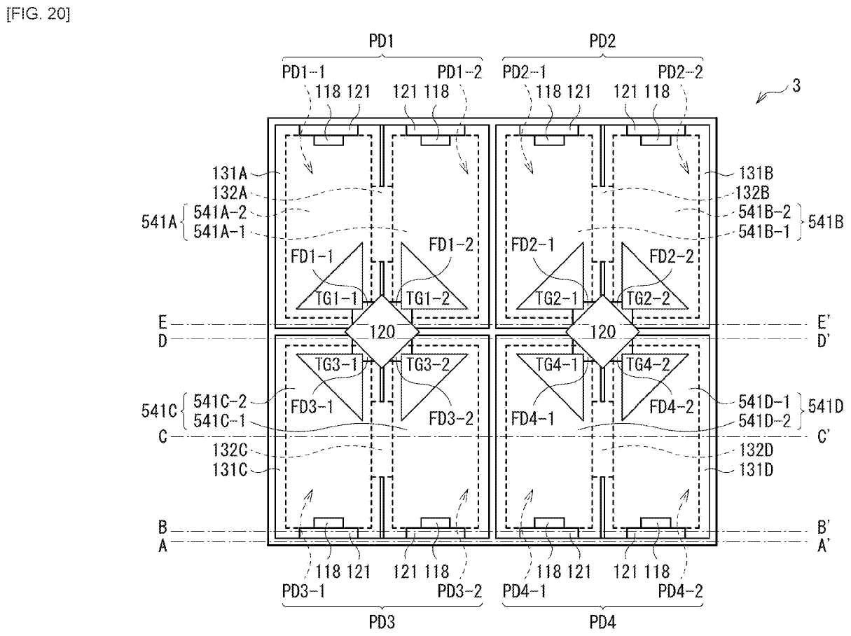

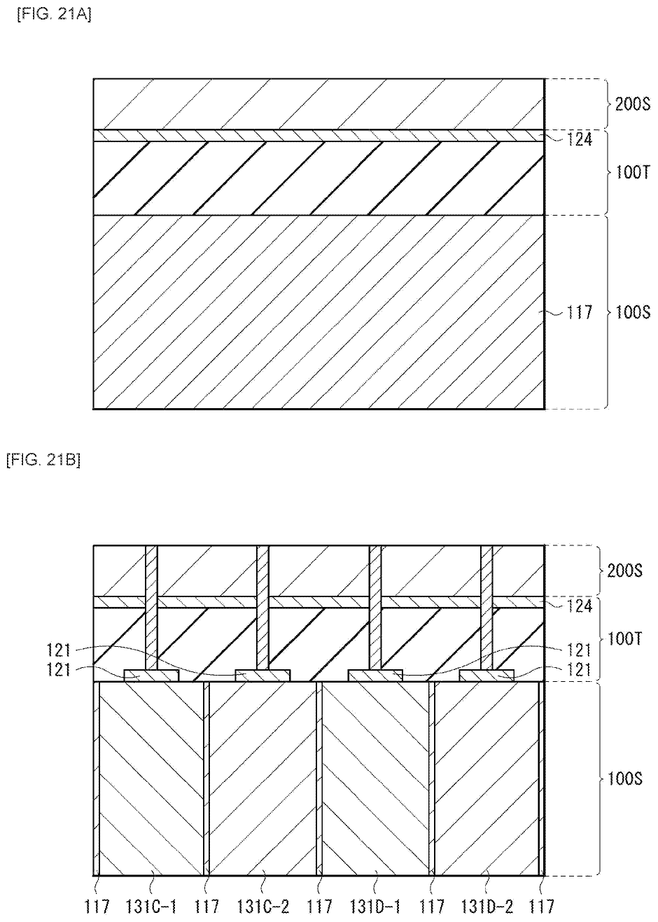

FIGS. 17A to 17C schematically illustrate the potential below the transfer gates TG, and the potentials of the first separation sections 131 and the second separation section 132 in an electric charge accumulation period (FIG. 17A), a non-selection period (FIG. 17B), and a readout period (FIG. 17C) in a case of a high gain. FIGS. 18A to 18C schematically illustrate the potential below the transfer gates TG, and the potentials of the first separation sections 131 and the second separation section 132 in an electric charge accumulation period (FIG. 18A), a non-selection period (FIG. 18B), and a readout period (FIG. 18C) in a case of a low gain. In general, signals are amplified with a high gain at low illuminance and with a low gain at high illuminance.

For example, the layer below the transfer gates TG has a negative (—) bias and the first separation sections 131 (PD-1 and PD-2) each have a positive (+) bias in the electric charge accumulation period in a case of a high gain. Specifically, as illustrated in FIG. 17A, the electric potential of the second separation section 132>the electric potential below the transfer gates TG is satisfied. In addition, the two photodiodes PD-1 and PD-2 and the second separation section 132 have a great electric potential difference (the electric potentials of the two photodiodes PD-1 and PD-2>>the electric potential of the second separation section 132). In contrast, for example, the layer below the transfer gates TG has a negative (—) bias and the first separation sections 131 (PD-1 and PD-2) each have a positive (+) bias in the electric charge accumulation period in a case of a low gain. Specifically, as illustrated in FIG. 18A, the two photodiodes PD-1 and PD-2 and the second separation section 132 have a small electric potential difference. In other words, the second separation section 132 and the layer below the transfer gates TG have a great electric potential difference (the electric potential of the second separation section 132>>the electric potential below the transfer gates TG). In this way, in the electric charge accumulation period in a case of a low gain in which the amount of output signals increases, the second separation section 132 has a higher electric potential (set closer to the positive (+) bias side) than in a case of a high gain. This makes it possible to reduce electric charge leaking to the adjacent pixel 541 and maintain the linearity during imaging.

As described above, it is possible in the imaging device 1 according to the present embodiment to achieve both the distance measurement performance (separation ratio) and the imaging performance (linearity).

The following describes modification examples (modification examples 1 and 2) of the embodiment described above, and an application example and practical application examples. The following assigns the same signs to components similar to those of the embodiment described above and omits descriptions thereof as appropriate.

### 2. MODIFICATION EXAMPLE 1

FIG. 19 schematically illustrates an example of a planar configuration of an imaging device (imaging device 2) according to a modification example 1 of the present disclosure. In the embodiment described above, the example has been described in which the plurality of transistors included in the pixel circuit 210 is provided in the semiconductor layer 200S different from the semiconductor layer 100S provided with the photodiodes PD, but this is not limitative. For example, the plurality of transistors included in the pixel circuit 210 may be provided in the semiconductor layer 100S.

The plurality of transistors (the reset transistor RST, the amplification transistor AMP, and the selection transistor SEL) included in the pixel circuit 210 may be provided, for example, along the H direction of pixels (the pixels 541A, 541B, 541C, and 541D) disposed in two rows and two columns, for example, as illustrated in FIG. 19.

### 3. MODIFICATION EXAMPLE 2

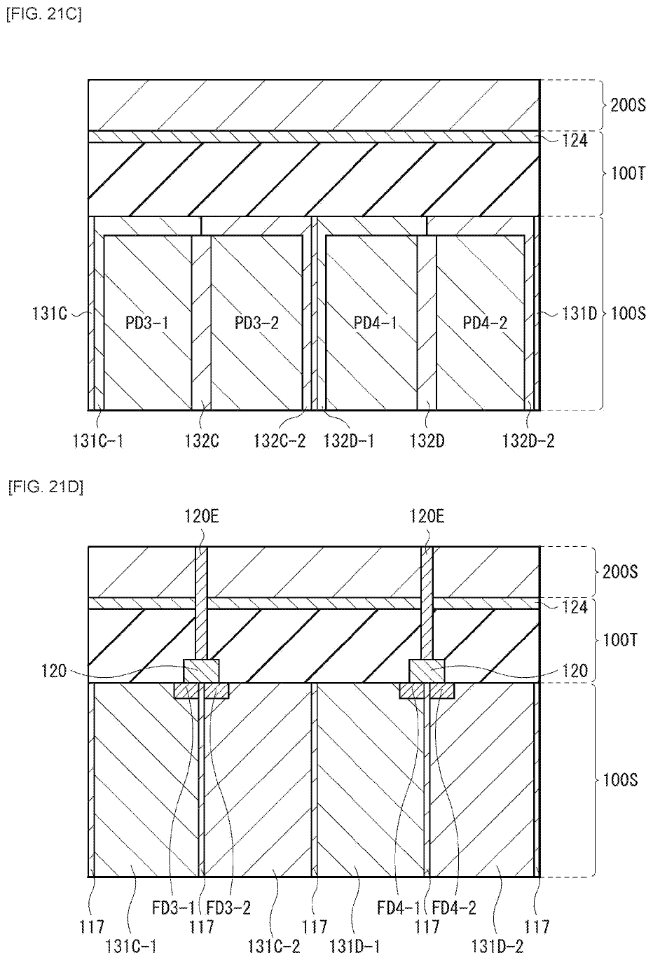

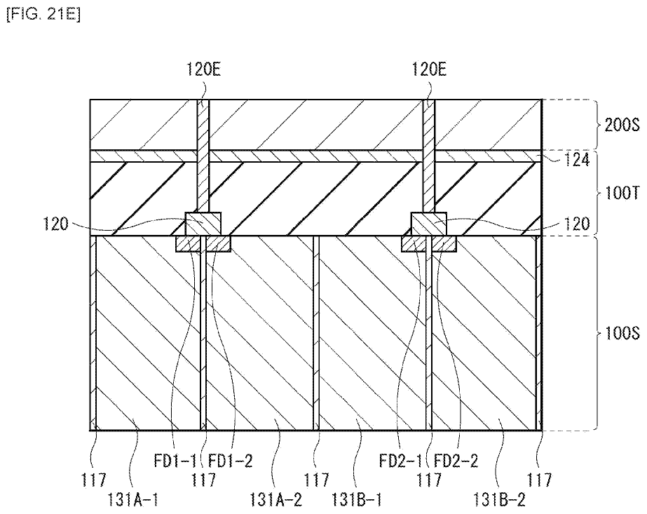

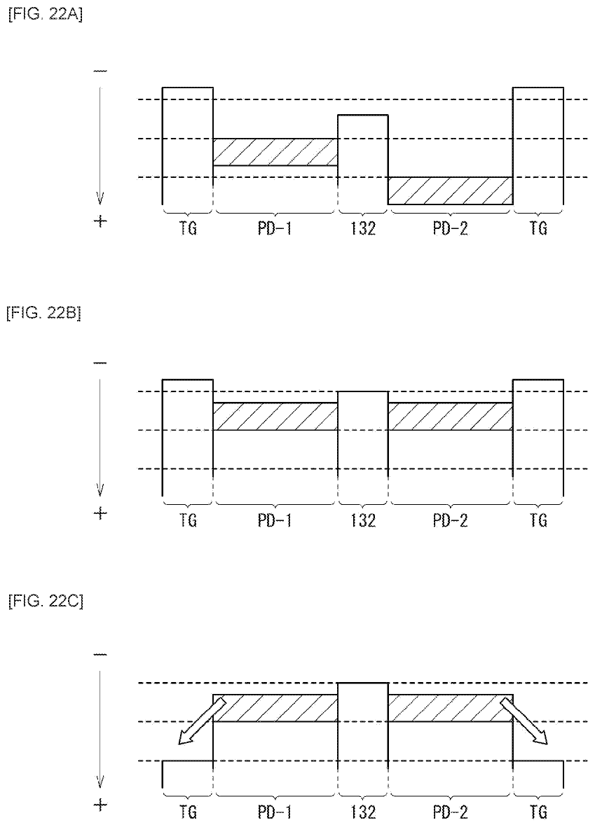

FIG. 20 schematically illustrates an example of a planar configuration of an imaging device (imaging device 3) according to a modification example 2 of the present disclosure. FIG. 21A schematically illustrates an example of a cross-sectional configuration of the imaging device 3 taken along an A-A′ line illustrated in FIG. 20. FIG. 21B schematically illustrates an example of a cross-sectional configuration of the imaging device 3 taken along a B-B′ line illustrated in FIG. 20. FIG. 21C schematically illustrates an example of a cross-sectional configuration of the imaging device 3 taken along a C-C′ line illustrated in FIG. 20. FIG. 21D schematically illustrates an example of a cross-sectional configuration of the imaging device 3 taken along a D-D′ line illustrated in FIG. 20. FIG. 21E schematically illustrates an example of a cross-sectional configuration of the imaging device 3 taken along an E-E′ line illustrated in FIG. 20.

In the embodiment described above, the example has been described in which electric potentials are collectively applied to the first separation sections 131 provided around the two photodiodes PD provided in each of the pixels 541A, 541B, 541C, and 541D. For example, individual electric potentials may also be, however, applied to first separation sections (e.g., a first separation section 131A-1 around the photodiode PD1-1 and a first separation section 131A-2 around the photodiode PD1-2) of the first separation sections 131 around the respective photodiodes PD. The first separation section 131A-1 and the first separation section 131A-2 are provided in the pixel 541A.

The first separation section 131-1 (the first separation section 131A-1, 131B-1, 131C-1, or 131D-1) surrounding the photodiode PD-1 on the left side in the pixel 541, a first separation section 131-2 (the first separation section 131A-2, 131B-2, 131C-2, or 131D-2) surrounding the photodiode PD-2 on the right side in the pixel 541, and the second separation section 132 each include, for example, a p-type semiconductor region. The first separation section 131-1 and the first separation section 131-2 are electrically separated from each other by the pixel separation section 117 and the second separation section 132 as in the embodiment described above. In the present modification example, the pad sections 121 are provided in the respective VSS contact regions 118. The respective VSS contact regions 118 are provided in the first separation section 131-1 and the first separation section 131-2. This makes it possible to apply respective individual electric potentials to the first separation section 131-1 and the first separation section 131-2.

FIGS. 22A to 22C schematically illustrate the potential below the transfer gates TG, and the potentials of the first separation sections 131-1 and 131-2 and the second separation section 132 of the pixel 541 in the imaging device 3 according to the present modification example in an electric charge accumulation period (FIG. 22A), a non-selection period (FIG. 22B), and a readout period (FIG. 22C). Electric potentials different from each other are applied to the first separation section 131-1 surrounding the photodiode PD-1 and the first separation section 131-2 surrounding the photodiode PD-2 in the pixel 541 as in the present modification example. This makes it possible to optionally adjust the saturation charge amounts Qs of the photodiodes PD-1 and PD-2, for example, in a case where uneven amounts of electric charge are accumulated in the two photodiodes PD-1 and PD-2.

### 4. OTHER MODIFICATION EXAMPLES

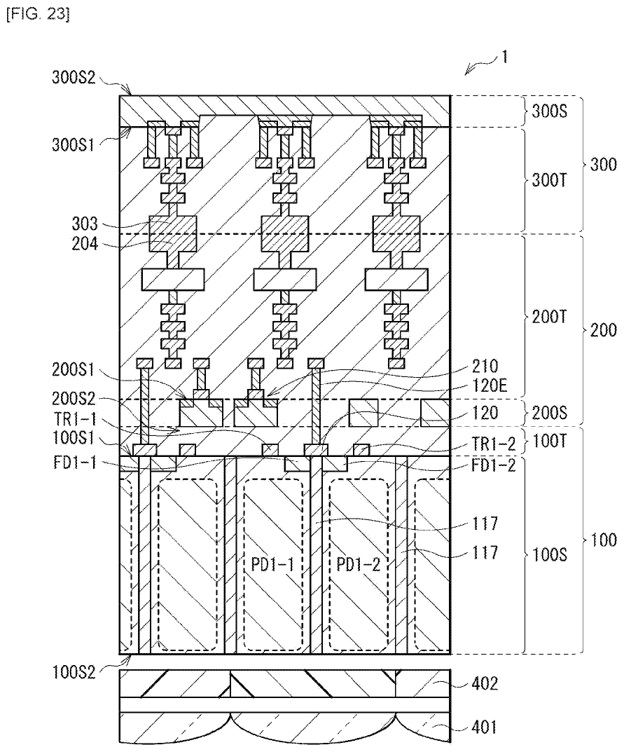

Each of FIGS. 23 to 25 schematically illustrates an example of a stacked structure of the first substrate 100, the second substrate 200, and the third substrate 300 in the imaging device 1, for example, illustrated in any of FIGS. 7 and 8.

In the imaging device 1, the first substrate 100 and the second substrate 200 may be electrically coupled, for example, by the through electrode 120E and the second substrate 200 and the third substrate 300 may be electrically coupled to each other, for example, by CuCu coupling, for example, through the contact sections 204 and 303 as illustrated in FIG. 23.

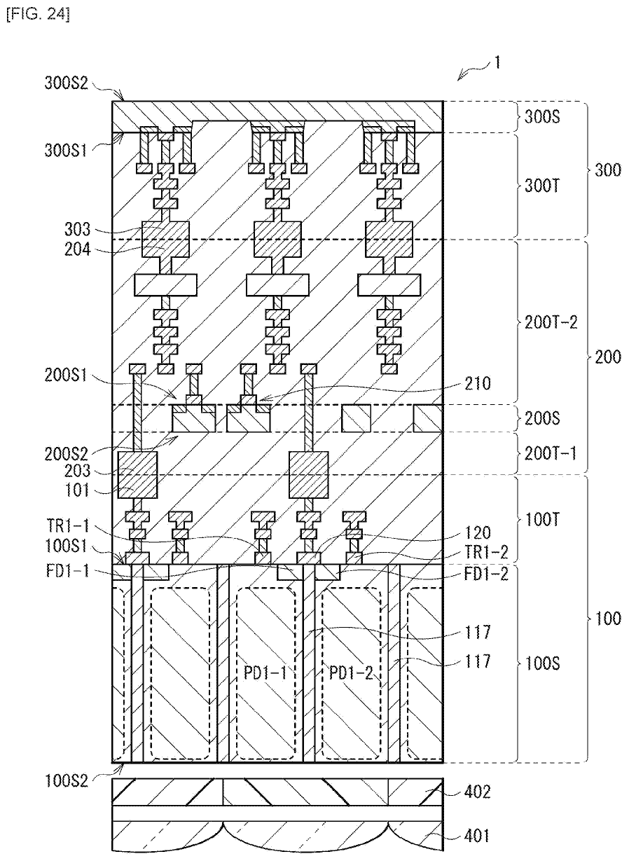

Alternatively, in the imaging device 1, the first substrate 100 and the second substrate 200 may be electrically coupled, for example, by CuCu coupling as illustrated in FIG. 24. Specifically, in the first substrate 100, a contact section 101 is formed on a front surface of the wiring layer 100T opposed to the second substrate 200. In the second substrate 200, a wiring layer 200T-1 is formed on a back surface 200S2 side of the semiconductor layer 200S opposed to the first substrate 100. The contact section 203 is formed on a surface of the wiring layer 200T-1 opposed to the first substrate 100. The first substrate 100 and the second substrate 200 may be electrically coupled to each other, for example, by CuCu coupling through these contact sections 101 and 203.

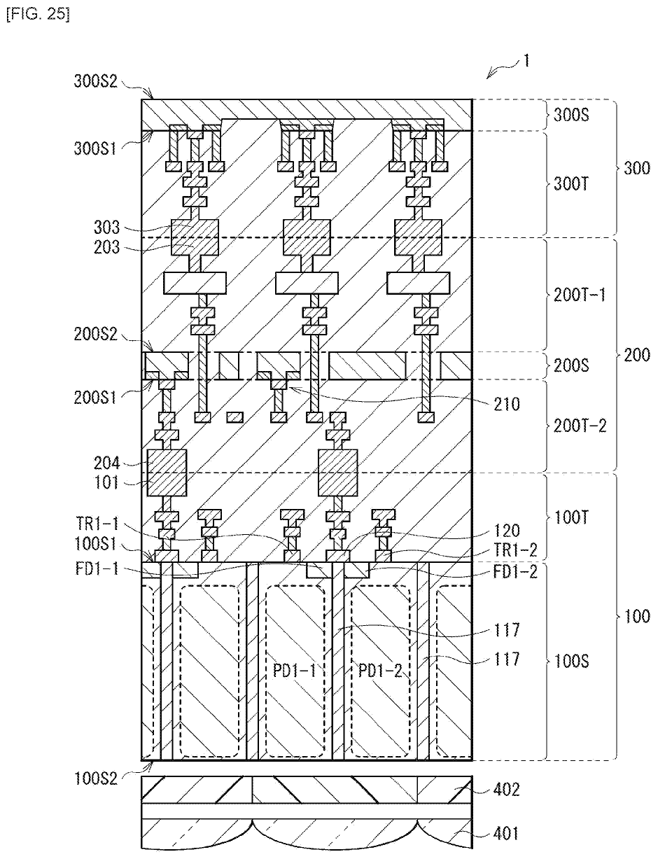

In addition, each of FIGS. 23 and 24 has illustrated the example in which the first substrate 100 and the second substrate 200 are bonded together face to back, but this is not limitative. As illustrated in FIG. 25, it is possible in the imaging device 1 to bond the first substrate 100 and the second substrate 200 face to face. In that case, the first substrate 100 and the second substrate 200 are electrically coupled to each other, for example, by CuCu coupling through the contact section 101 and the contact section 204. The contact section 101 is formed on the front surface of the wiring layer 100T. The contact section 204 is formed on a front surface of a wiring layer 200T-2 provided on a front surface 200S1 side of the semiconductor layer 200S in the second substrate 200. The second substrate 200 and the third substrate 300 are electrically coupled to each other, for example, by CuCu coupling, for example, through the contact section 203 and the contact section 303 on the third substrate 300 side. The contact section 203 is formed on a surface of the wiring layer 200T-1 provided on the back surface 200S2 side of the semiconductor layer 200S.

It is to be noted that each of FIGS. 23 to 25 has illustrated the example in which the semiconductor layer 100S of the first substrate 100 has the pixel configuration illustrated in any of FIGS. 7 and 8, but this is not limitative. The stacked structure described above is also applicable, for example, to an imaging device having the pixel structure illustrated in FIG. 6. Alternatively, the stacked structure described above is applicable to the imaging devices 2 and 3 described in the modification examples 1 and 2 described above. In addition, contact sections (e.g., the contact sections 101, 203, 204, and 303) that electrically couple the first substrate 100, the second substrate 200, and the third substrate 300 to each other may be each formed by using a metal material other than copper (Cu) or an electric conductor. For example, the contact sections 101, 203, 204, and 303 may be each formed by using metal including one or more metal materials such as copper (Cu), aluminum (Al), or gold (Au), Cu alloy, polysilicon, or the like.

### 5. APPLICATION EXAMPLE

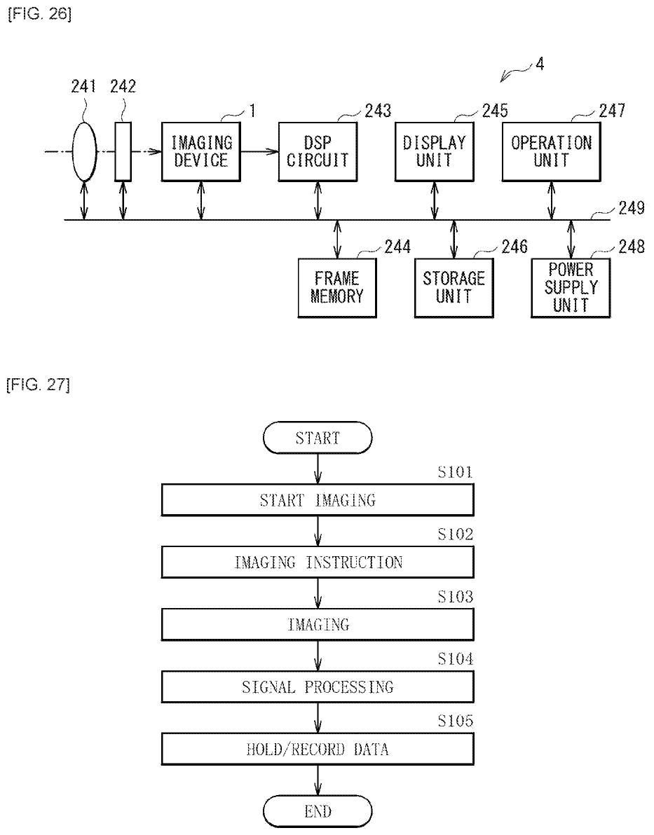

FIG. 26 illustrates an example of a schematic configuration of an imaging system 4 including the imaging device (e.g., the imaging device 1) according to any of the embodiment described above and the modification examples thereof.

The imaging system 4 is, for example, an electronic apparatus including an imaging device such as a digital still camera or a video camera, a mobile terminal device such as a smartphone or a tablet terminal, or the like. The imaging system 4 includes, for example, the imaging device 1 according to any of the embodiment described above and the modification examples thereof, a DSP circuit 243, a frame memory 244, a display unit 245, a storage unit 246, an operation unit 247, and a power supply unit 248. In the imaging system 4, the imaging device 1 according to any of the embodiment described above and the modification examples thereof, the DSP circuit 243, the frame memory 244, the display unit 245, the storage unit 246, the operation unit 247, and the power supply unit 248 are coupled to each other through a bus line 249.

The imaging device 1 according to any of the embodiment described above and the modification examples thereof outputs image data corresponding to incident light. The DSP circuit 243 is a signal processing circuit that processes a signal (image data) outputted from the imaging device 1 according to any of the embodiment described above and the modification examples thereof. The frame memory 244 temporarily holds the image data processed by the DSP circuit 243 in units of frames. The display unit 245 includes, for example, a panel-type display such as a liquid crystal panel or an organic EL (Electro Luminescence) panel and displays a moving image or a still image captured by the imaging device 1 according to any of the embodiment described above and the modification examples thereof. The storage unit 246 records the image data of a moving image or a still image captured by the imaging device 1 according to any of the embodiment described above and the modification examples thereof in a recording medium such as a semiconductor memory or a hard disk. The operation unit 247 issues an operation instruction for the various functions of the imaging system 4 in accordance with an operation by a user. The power supply unit 248 appropriately supplies various kinds of power for operation to the imaging device 1 according to any of the embodiment described above and the modification examples thereof, the DSP circuit 243, the frame memory 244, the display unit 245, the storage unit 246, and the operation unit 247 that are supply targets.

Next, an imaging procedure in the imaging system 4 is described.

FIG. 27 illustrates an example of a flowchart of an imaging operation in the imaging system 4. A user issues an instruction to start imaging by operating the operation unit 247 (step S101). The operation unit 247 then transmits an imaging instruction to the imaging device 1 (step S102). The imaging device 1 (specifically, a system control circuit 36) executes imaging in a predetermined imaging scheme upon receiving the imaging instruction (step S103).

The imaging device 1 outputs image data offered by the imaging to the DSP circuit 243. Here, the image data refers to data for all of the pixels of pixel signals generated on the basis of the electric charge temporarily held in the floating diffusion FD. The DSP circuit 243 performs predetermined signal processing (e.g., a noise reduction process or the like) on the basis of the image data inputted from the imaging device 1 (step S104). The DSP circuit 243 causes the frame memory 244 to hold the image data subjected to the predetermined signal processing and the frame memory 244 causes the storage unit 246 to store the image data (step S105). In this way, the imaging in the imaging system 4 is performed.

In the present application example, the imaging device 1 according to any of the embodiment described above and the modification examples thereof is applied to the imaging system 4. This allows the imaging device 1 to be smaller in size or higher in definition. This makes it possible to provide the small or high-definition imaging system 4.

### 6. PRACTICAL APPLICATION EXAMPLES

### Practical Application Example 1

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an airplane, a drone, a vessel, or a robot.

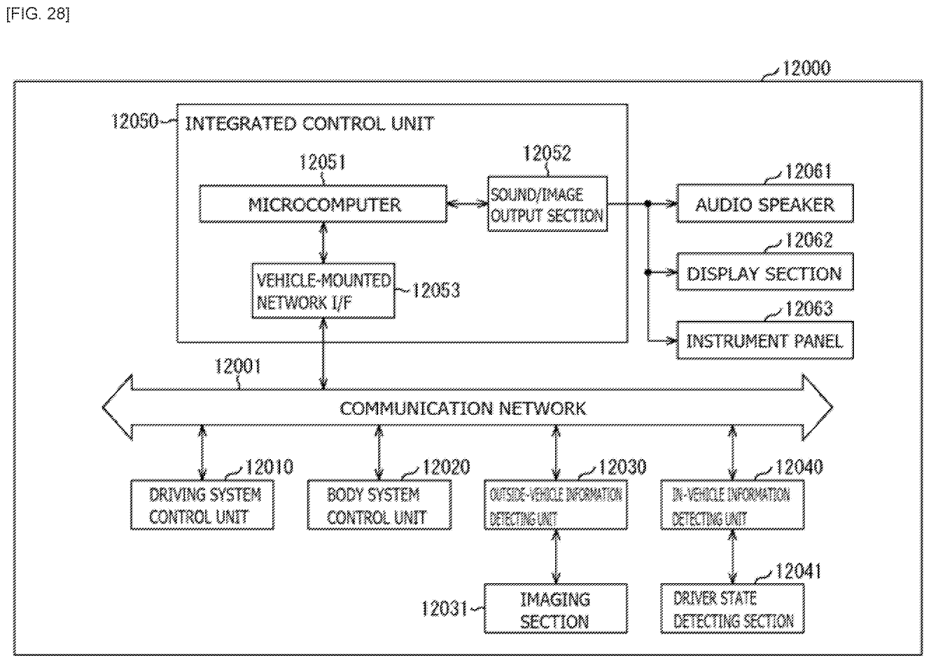

FIG. 28 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 28, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 57, an audio speaker 12061, a display section 12062, and an instrument panel 12063 are illustrated as the output device. The display section 12062 may, for example, include at least one of an on-board display and a head-up display.

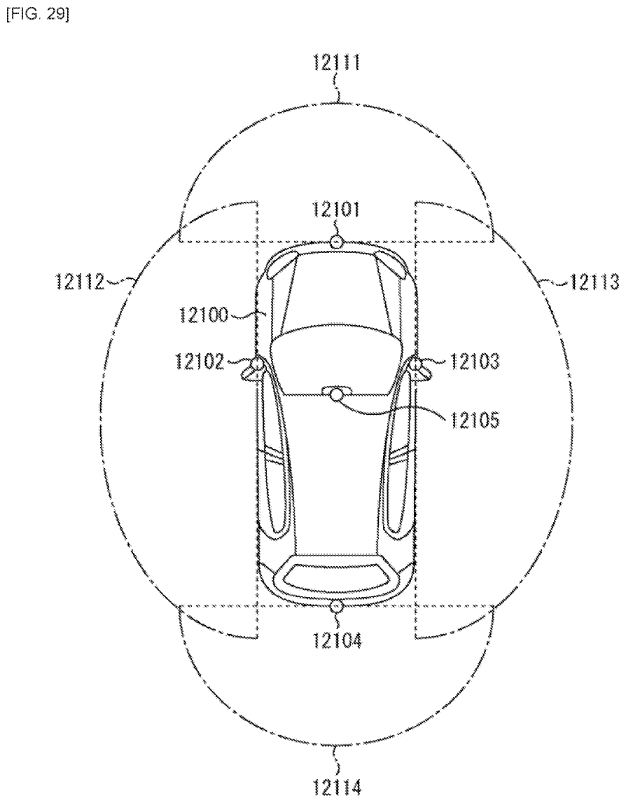

FIG. 29 is a diagram depicting an example of the installation position of the imaging section 12031.

In FIG. 29, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 29 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The above has described the example of the mobile body control system to which the technology according to the present disclosure may be applied. The technology according to the present disclosure may be applied to the imaging section 12031 among the components described above. Specifically, the imaging device 1 according to any of the embodiment described above and the modification examples thereof is applicable to the imaging section 12031. The application of the technology according to the present disclosure to the imaging section 12031 makes it possible to obtain a high-definition shot image with less noise and it is thus possible to perform highly accurate control using the shot image in the mobile body control system.

### Practical Application Example 2

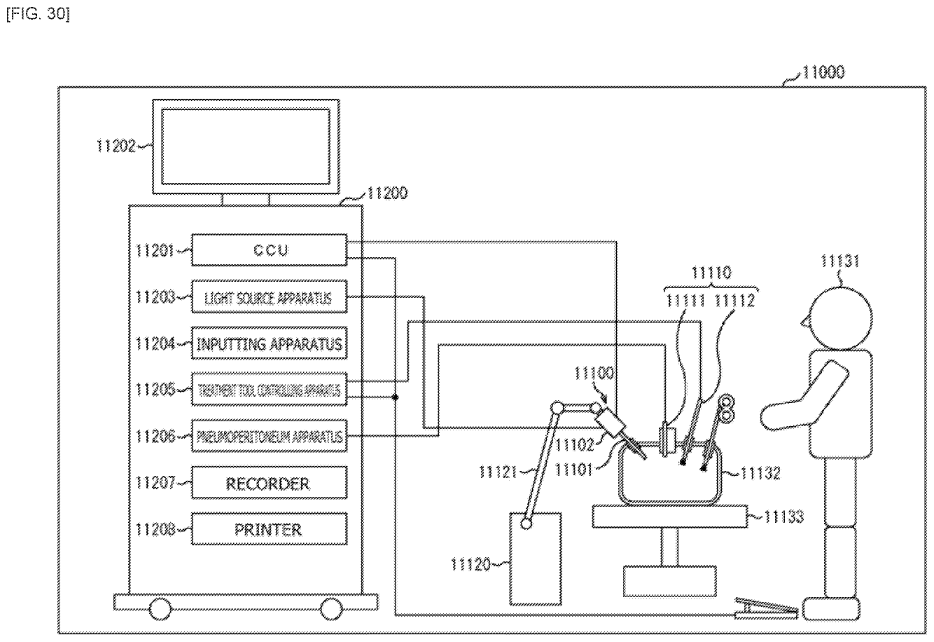

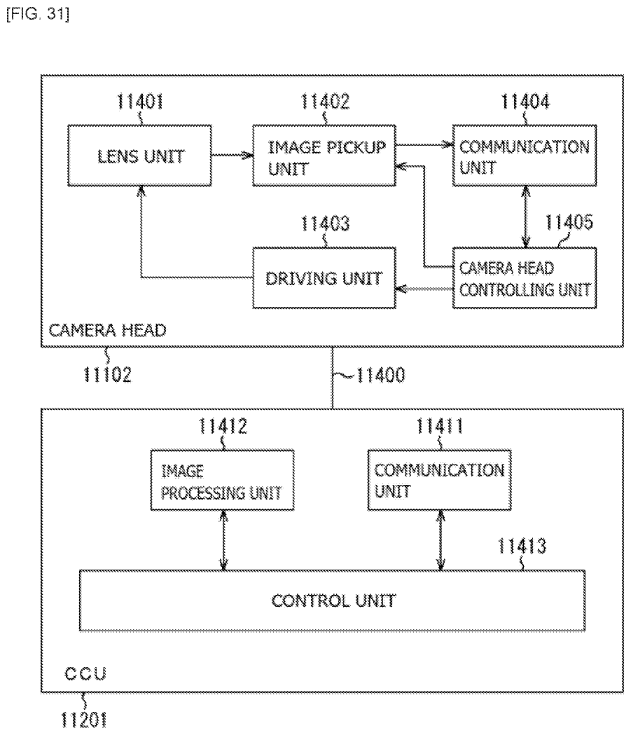

FIG. 30 is a view depicting an example of a schematic configuration of an endoscopic surgery system to which the technology according to an embodiment of the present disclosure (present technology) can be applied.

In FIG. 30, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

FIG. 31 is a block diagram depicting an example of a functional configuration of the camera head 11102 and the CCU 11201 depicted in FIG. 30.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The above has described the example of the endoscopic surgery system to which the technology according to the present disclosure may be applied. The technology according to the present disclosure may be favorably applied to the image pickup unit 11402 provided to the camera head 11102 of the endoscope 11100 among the components described above. The application of the technology according to the present disclosure to the image pickup unit 11402 allows the image pickup unit 11402 to be smaller in size or higher in definition and it is thus possible to provide the small or high-definition endoscope 11100.

Although the present disclosure has been described above with reference to the embodiment and the modification examples 1 and 2, and the application example and the practical application examples, the present disclosure is not limited to the embodiment and the like described above. A variety of modifications are possible.

It is to be noted that the effects described herein are merely illustrative. The effects according to the present disclosure are not limited to the effects described herein. The present disclosure may have effects other than the effects described herein.

It is to be noted that the present disclosure may also have configurations as follows. According to the following configurations, the first separation sections and the second separation section are provided in the one pixel including the plurality of photoelectric conversion regions disposed side by side in the plane of the semiconductor substrate. The electric potentials are individually applied to the layer below the first transistor provided above each of the plurality of photoelectric conversion regions and the first separation sections to indirectly control the electric potential of the second separation section. The first separation sections surround the plurality of respective photoelectric conversion regions. The second separation section is adjacent to the first separation sections between the plurality of adjacent photoelectric conversion regions. This makes it possible to adjust the potentials of the first separation sections and the second separation section as appropriate at desired values after a wafer is fabricated. It is possible to achieve both the distance measurement performance and the imaging performance.

(1)

An imaging device including:
a pixel in which a plurality of photoelectric conversion regions is formed side by side in a plane of a semiconductor substrate;
a first transistor that is provided above each of the plurality of photoelectric conversion regions, the first transistor extracting electric charge generated in each of the plurality of photoelectric conversion regions;
first separation sections that are continuously provided around the plurality of photoelectric conversion regions; and
a second separation section that is provided adjacent to the first separation sections between the plurality of adjacent photoelectric conversion regions, the second separation section having a predetermined electric potential indirectly applied thereto by individually applying electric potentials to a layer below the first transistor and the first separation sections.
   (2)

The imaging device according to (1), in which the electric potentials of the first separation sections, the electric potential of the second separation section, and the electric potential below the first transistor each vary over time.

(3)

The imaging device according to (1) or (2), in which the electric potentials of the first separation sections are each higher than the electric potential of the second separation section.

(4)

The imaging device according to any one of (1) to (3), in which the electric potential below the first transistor is lower than the electric potential of the second separation section in an electric charge accumulation period in which electric charge is accumulated in the plurality of photoelectric conversion regions and the electric potential below the first transistor is higher than the electric potential of the second separation section in a readout period in which the electric charge accumulated in the plurality of photoelectric conversion regions is read out.

(5)

The imaging device according to any one of (1) to (4), in which the electric potential below the first transistor and the electric potential of the second separation section have substantially same electric potentials in a non-selection period of the pixel.

(6)

The imaging device according to any one of (1) to (5), in which an electric potential difference between the electric potential below the first transistor and the electric potential of the second separation section is different in accordance with an amount of incident light.

(7)

The imaging device according to (6), in which the electric potential difference between the electric potential below the first transistor and the electric potential of the second separation section in an electric charge accumulation period in which electric charge is accumulated in the plurality of photoelectric conversion regions at high illuminance is greater than the electric potential difference between the electric potential below the first transistor and the electric potential of the second separation section in the electric charge accumulation period in which the electric charge is accumulated in the plurality of photoelectric conversion regions at low illuminance.

(8)

The imaging device according to any one of (1) to (7), in which an electric potential difference between the electric potential below the first transistor and the electric potential of the second separation section is different in accordance with an analog gain.

(9)

The imaging device according to (8), in which the electric potential difference between the electric potential below the first transistor and the electric potential of the second separation section in an electric charge accumulation period in which electric charge is accumulated in the plurality of photoelectric conversion regions in a case of a low gain is greater than the electric potential difference between the electric potential below the first transistor and the electric potential of the second separation section in the electric charge accumulation period in which the electric charge is accumulated in the plurality of photoelectric conversion regions in a case of a high gain.

(10)

The imaging device according to any one of (1) to (9), in which an electric potential difference between the electric potential below the first transistor and the electric potential of the second separation section is different between autofocusing and imaging.

(11)

The imaging device according to (10), in which the electric potential difference between the electric potential below the first transistor and the electric potential of the second separation section in an electric charge accumulation period in which electric charge is accumulated in the plurality of photoelectric conversion regions during the imaging is greater than the electric potential difference between the electric potential below the first transistor and the electric potential of the second separation section in the electric charge accumulation period in which the electric charge is accumulated in the plurality of photoelectric conversion regions during the autofocusing.

(12)

The imaging device according to any one of (1) to (11), in which well electric potentials of the plurality of photoelectric conversion regions provided in the pixel are set for the plurality of respective photoelectric conversion regions.

(13)

The imaging device according to any one of (1) to (12), in which the first separation sections and the second separation section each include a p-type semiconductor region.

(14)

The imaging device according to any one of (1) to (13), further including: a first substrate in which the plurality of photoelectric conversion regions is formed side by side as the pixel to be buried in a plane of the semiconductor substrate;

a second substrate that is stacked on the first substrate, the second substrate being provided with at least a portion of second transistors included in a pixel circuit that outputs a pixel signal based on electric charge outputted from the pixel; and a through wiring line that electrically couples the first substrate and the second substrate.

This application claims the priority on the basis of Japanese Patent Application No. 2020-193592 filed with Japan Patent Office on Nov. 20, 2020, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. An imaging device comprising:
a pixel in which a plurality of photoelectric conversion regions is formed side by side in a plane of a semiconductor substrate;
a first transistor that is provided above each of the plurality of photoelectric conversion regions, the first transistor extracting electric charge generated in each of the plurality of photoelectric conversion regions;
first separation sections that are continuously provided around the plurality of photoelectric conversion regions; and
a second separation section that is provided adjacent to the first separation sections between the plurality of adjacent photoelectric conversion regions, the second separation section having a predetermined electric potential indirectly applied thereto by individually applying electric potentials to a layer below the first transistor and the first separation sections.

2. The imaging device according to claim 1, wherein the electric potentials of the first separation sections, the electric potential of the second separation section, and the electric potential below the first transistor each vary over time.

3. The imaging device according to claim 1, wherein the electric potentials of the first separation sections are each higher than the electric potential of the second separation section.

4. The imaging device according to claim 1, wherein the electric potential below the first transistor is lower than the electric potential of the second separation section in an electric charge accumulation period in which electric charge is accumulated in the plurality of photoelectric conversion regions and the electric potential below the first transistor is higher than the electric potential of the second separation section in a readout period in which the electric charge accumulated in the plurality of photoelectric conversion regions is read out.

5. The imaging device according to claim 1, wherein the electric potential below the first transistor and the electric potential of the second separation section have substantially same electric potentials in a non-selection period of the pixel.

6. The imaging device according to claim 1, wherein an electric potential difference between the electric potential below the first transistor and the electric potential of the second separation section is different in accordance with an amount of incident light.

7. The imaging device according to claim 6, wherein the electric potential difference between the electric potential below the first transistor and the electric potential of the second separation section in an electric charge accumulation period in which electric charge is accumulated in the plurality of photoelectric conversion regions at high illuminance is greater than the electric potential difference between the electric potential below the first transistor and the electric potential of the second separation section in the electric charge accumulation period in which the electric charge is accumulated in the plurality of photoelectric conversion regions at low illuminance.

8. The imaging device according to claim 1, wherein an electric potential difference between the electric potential below the first transistor and the electric potential of the second separation section is different in accordance with an analog gain.

9. The imaging device according to claim 8, wherein the electric potential difference between the electric potential below the first transistor and the electric potential of the second separation section in an electric charge accumulation period in which electric charge is accumulated in the plurality of photoelectric conversion regions in a case of a low gain is greater than the electric potential difference between the electric potential below the first transistor and the electric potential of the second separation section in the electric charge accumulation period in which the electric charge is accumulated in the plurality of photoelectric conversion regions in a case of a high gain.

10. The imaging device according to claim 1, wherein an electric potential difference between the electric potential below the first transistor and the electric potential of the second separation section is different between autofocusing and imaging.

11. The imaging device according to claim 10, wherein the electric potential difference between the electric potential below the first transistor and the electric potential of the second separation section in an electric charge accumulation period in which electric charge is accumulated in the plurality of photoelectric conversion regions during the imaging is greater than the electric potential difference between the electric potential below the first transistor and the electric potential of the second separation section in the electric charge accumulation period in which the electric charge is accumulated in the plurality of photoelectric conversion regions during the autofocusing.

12. The imaging device according to claim 1, wherein well electric potentials of the plurality of photoelectric conversion regions provided in the pixel are set for the plurality of respective photoelectric conversion regions.

13. The imaging device according to claim 1, wherein the first separation sections and the second separation section each include a p-type semiconductor region.

14. The imaging device according to claim 1, further comprising:
a first substrate in which the plurality of photoelectric conversion regions is formed side by side as the pixel to be buried in a plane of the semiconductor substrate;
a second substrate that is stacked on the first substrate, the second substrate being provided with at least a portion of second transistors included in a pixel circuit that outputs a pixel signal based on electric charge outputted from the pixel; and
a through wiring line that electrically couples the first substrate and the second substrate.
